(19) United States
(12) Patent Application Publication
(10) Pub. No.: US 2026/0155180 A1
(43) Pub. Date: Jun. 4, 2026

(54) MEMORY DEVICE AND MEMORY SYSTEM INCLUDING THE SAME

(71) Applicant: Samsung Electronics Co., Ltd., Suwon-si (KR)

(72) Inventors: Sanggi Hong, Suwon-si (KR); Resen Ahn, Suwon-si (KR); Seunghyun Moon, Suwon-si (KR); Sung-Min Joe, Suwon-si (KR); Donghyuk Chae, Suwon-si (KR)

(21) Appl. No.: 19/326,623

(22) Filed: Sep. 11, 2025

(30) Foreign Application Priority Data
Dec. 4, 2024 (KR) 10-2024-0178475

(51) Int. Cl. G11C 16/08; G11C 16/04; G11C 16/10; G11C 16/14; G11C 16/24; G11C 16/26; G11C 16/34

(52) U.S. Cl. CPC G11C 16/08; G11C 16/0483; G11C 16/10; G11C 16/14; G11C 16/24; G11C 16/26; G11C 16/3459

(57) ABSTRACT

An example memory device includes a first wafer that includes a first sub-memory block connected to first to n-th word lines, a first bit line, a first string selection line, and a first ground selection line, and a second wafer that is stacked on the first wafer in a vertical direction and includes a second sub-memory block connected to (n+1)-th to 2n-th word lines, a second bit line, a second string selection line, and a second ground selection line. The first to n-th word lines are respectively connected to the (n+1)-th to 2n-th word lines and share first to n-th word line drivers with the (n+1)-th to 2n-th word lines. The first bit line is connected to the second bit line and shares a first page buffer with the second bit line.

### CROSS-REFERENCE TO RELATED APPLICATION

This application claims priority under 35 U.S.C. § 119 to Korean Patent Application No. 10-2024-0178475 filed on Dec. 4, 2024, in the Korean Intellectual Property Office, the disclosures of which are incorporated by reference herein in their entireties.

### BACKGROUND

A semiconductor memory device is classified as a volatile memory such as a DRAM or an SRAM or a nonvolatile memory such as an EEPROM, an FRAM, a PRAM, an MRAM, or a flash memory. The volatile memory loses data stored when a power is turned off, but the nonvolatile memory retains data stored therein when a power is turned off.

Nowadays, devices using the nonvolatile memory are increasing. For example, a digital camera, a mobile phone, a solid state disk (SSD), etc. use the nonvolatile memory as a storage device. Because the flash memory among the nonvolatile memories supports a function of electrically erasing data of cells at the same time, instead of the hard disk, the flash memory is being widely used as a storage device.

### SUMMARY

The present disclosure relates to a memory device and a memory system including the same.

In general, according to some aspects, a memory device includes a first wafer that includes a first sub-memory block connected to first to n-th word lines, a first bit line, a first string selection line, and a first ground selection line, and a second wafer that is stacked on the first wafer in a vertical direction and includes a second sub-memory block connected to (n+1)-th to 2n-th word lines, a second bit line, a second string selection line, and a second ground selection line. The first to n-th word lines are respectively connected to the (n+1)-th to 2n-th word lines and share first to n-th word line drivers with the (n+1)-th to 2n-th word lines. The first bit line is connected to the second bit line and shares a first page buffer with the second bit line. The first string selection line is connected to a first string selection driver, and the second string selection line is connected to a second string selection driver. The first ground selection line is connected to a first ground selection driver, the second ground selection line is connected to a second ground selection drive, and “n” is a natural number more than 1.

In general, according to some aspects, a memory system includes a memory controller that generates a command indicating a memory operation, and a memory device that performs the memory operation based on the command. The memory device includes a first wafer that includes a first sub-memory block connected to first to n-th word lines, a first bit line, a first string selection line, and a first ground selection line, and a second wafer that is stacked on the first wafer in a vertical direction and includes a second sub-memory block connected to (n+1)-th to 2n-th word lines, a second bit line, a second string selection line, and a second ground selection line. The first to n-th word lines are respectively connected to the (n+1)-th to 2n-th word lines and share first to n-th word line drivers with the (n+1)-th to 2n-th word lines. The first bit line is connected to the second bit line and shares a first page buffer with the second bit line. The first string selection line is connected to a first string selection driver, and the second string selection line is connected to a second string selection driver. The first ground selection line is connected to a first ground selection driver, the second ground selection line is connected to a second ground selection driver, and “n” is a natural number more than 1.

In general, according to some aspects, a memory device includes a first wafer that includes a first sub-memory block, the first sub-memory block connected to a first string selection line and a first ground selection line, and a second wafer that is stacked on the first wafer in a vertical direction and includes a second sub-memory block, the second sub-memory block connected to a second string selection line and a second ground selection line. The first sub-memory block and the second sub-memory block share first to n-th word lines and a first bit line. In memory operations associated with the first sub-memory block and the second sub-memory block, a voltage magnitude or an application time of a voltage applied to at least one line connected to each of the first sub-memory block and the second sub-memory block is differently set in each of the first sub-memory block and the second sub-memory block, and “n” is a natural number more than 1.

### BRIEF DESCRIPTION OF THE DRAWINGS

The above and other objects and features of the present disclosure will become apparent by describing in implementations thereof with reference to the accompanying drawings.

FIG. 1 is a block diagram schematically illustrating an example of a memory device.

FIG. 2 is an example circuit diagram describing how the word line driver WD of FIG. 1 is shared.

FIG. 3 is a block diagram of an example of a memory device.

FIG. 4 is a circuit diagram illustrating an example of a first sub-memory block of FIG. 1 in detail.

FIG. 5 is a diagram schematically illustrating an example of a cross section of a memory block of FIG. 1.

FIG. 6 is a diagram describing example threshold voltage distributions of memory cell.

FIG. 7 is a diagram describing an example of a method of adjusting a threshold voltage distribution of memory cells.

FIG. 8 is a diagram illustrating an example of a page buffer of FIG. 3 in detail.

FIG. 9 is a timing diagram describing an example of a program operation on a first wafer.

FIG. 10 is a timing diagram describing an example of a program operation on a second wafer.

FIG. 11 is a timing diagram describing an example of a read operation on a first wafer.

FIG. 12 is a timing diagram describing an example of a read operation on a second wafer.

FIG. 13 is a timing diagram describing an example of a pre-program operation in an erase sequence of a memory block.

FIG. 14 is a diagram schematically illustrating an example of a cross section of a memory block further including selection lines.

FIG. 15 is a timing diagram describing an example of an erase operation in an erase sequence of a memory block.

FIG. 16 is a diagram schematically illustrating an example of a cross section of a memory block connected to two common source drivers.

FIG. 17 is a timing diagram describing an example of a pre-program operation in an erase sequence of a memory block of FIG. 16.

FIG. 18 is a diagram schematically illustrating an example of a cross section of a memory block of FIG. 16, which further includes GIDL lines.

FIG. 19 is a timing diagram describing an example of an erase operation in an erase sequence of a memory block of FIG. 18.

FIG. 20 is a block diagram of an example of a memory system.

### DETAILED DESCRIPTION

Below, implementations of the present disclosure will be described in detail and clearly to such an extent that one skilled in the art carries out implementations of the present disclosure easily.

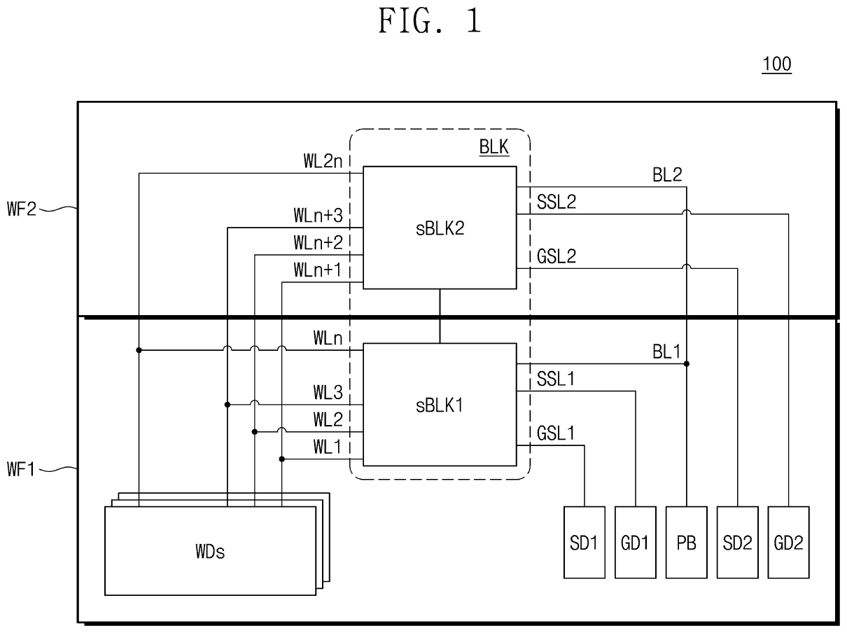

FIG. 1 is a block diagram schematically illustrating an example of a memory device 100. Referring to FIG. 1, the memory device 100 may include a first wafer WF1 and a second wafer WF2.

The memory device 100 may be implemented with any one of various types of nonvolatile memory devices such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase-change random access memory (PRAM) using chalcogenide alloys, and a resistive random access memory (ReRAM) using transition metal oxide.

The first wafer WF1 and the second wafer WF2 may be stacked in a vertical direction. An example in which the second wafer WF2 is stacked on the first wafer WF1 in the vertical direction is illustrated in FIG. 1, but the present disclosure is not limited thereto. For example, the first wafer WF1 may be disposed on the second wafer WF2.

In some implementations, the first wafer WF1 and the second wafer WF2 may be produced by different processes. Alternatively, the first wafer WF1 and the second wafer WF2 may be wafers which are produced by substantially the same process. Alternatively, in some implementations, the first wafer WF1 and the second wafer WF2 may be included in different portions in one process wafer produced through the process.

In some implementations, the memory device 100 may have a non-monolithic structure. The non-monolithic structure refers to a structure in which the first wafer WF1 and the second wafer WF2 constituting the memory device 100 are individually produced and are then bonded to each other by a bonding technology. For example, the first wafer WF1 and the second wafer WF2 may be bonded to each other by the hybrid bonding.

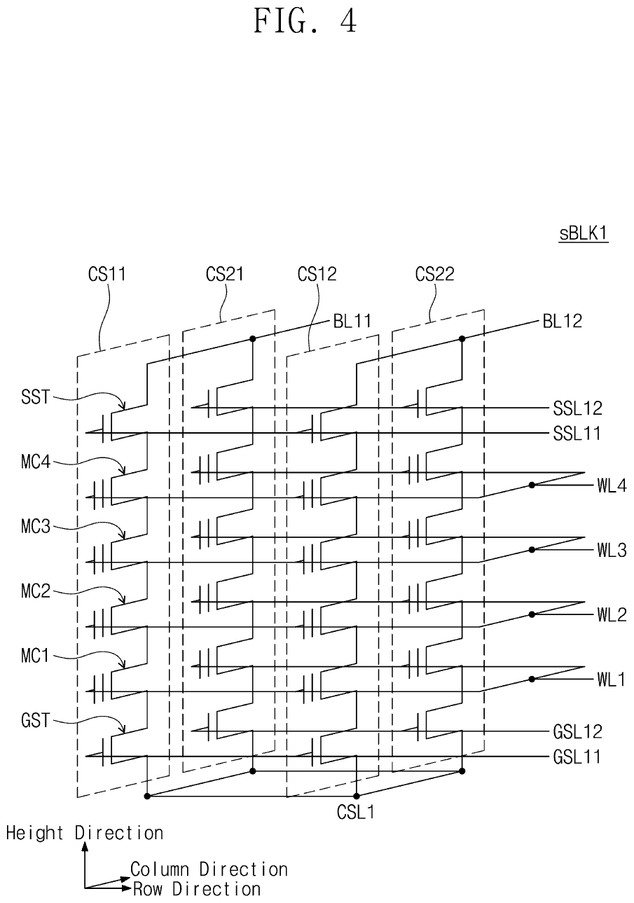

The first wafer WF1 may include a first sub-memory block sBLK1. The first sub-memory block sBLK1 may include a plurality of memory cells. For example, the first sub-memory block sBLK1 may store data of 16 KB. This will be described in detail with reference to FIG. 4. The first wafer WF1 may include a plurality of word line drivers WDs, a page buffer PB, a first string selection driver SD1, a second string selection driver SD2, a first ground selection driver GD1, and a second ground selection driver GD2. For convenience of description, the drivers and the page buffer PB are illustrated as being included in the first wafer WF1, but the present disclosure is not limited thereto. For example, the drivers and the page buffer PB may be included in the second wafer WF2. Alternatively, the drivers and the page buffer PB may be implemented in a third wafer independent of the first wafer WF1 and the second wafer WF2. In this case, the third wafer may be stacked to be vertical with respect to the first wafer WF1 and the second wafer WF2.

The first wafer WF1 may include first to n-th word lines WL1 to WLn, a first bit line BL1, a first string selection line SSL1, and a first ground selection line GSL1. In this case, “n” is a natural number greater than 1. The first sub-memory block sBLK1 may be connected to first to n-th word line drivers WD1 to WDn through the first to n-th word lines WL1 to WLn, respectively. The first sub-memory block sBLK1 may be connected to the page buffer PB through the first bit line BL1. The first sub-memory block sBLK1 may be connected between the first string selection driver SD1 through the first string selection line SSL1. The first sub-memory block sBLK1 may be connected between the first ground selection driver GD1 through the first ground selection line GSL1.

The second wafer WF2 may include a second sub-memory block sBLK2. The second sub-memory block sBLK2 may include a plurality of memory cells. For example, the second sub-memory block sBLK2 may store data of 16 KB. In this case, the first sub-memory block sBLK1 of the first wafer WF1 and the second sub-memory block sBLK2 of the second wafer WF2 may be referred to as “one memory block BLK”. The memory block BLK may be a unit of an erase operation to be described later.

The second wafer WF2 may include (n+1)-th to 2n-th word lines WLn+1 to WL2n, a second bit line BL2, a second string selection line SSL2, and a second ground selection line GSL2. The second sub-memory block sBLK2 may be connected to the first to n-th word line drivers WD1 to WDn through the (n+1)-th to 2n-th word lines WLn+1 to WL2n, respectively. The second sub-memory block sBLK2 may be connected to the page buffer PB through the second bit line BL2. The second sub-memory block sBLK2 may be connected to the second string selection driver SD2 through the second string selection line SSL2. The second sub-memory block sBLK2 may be connected to the second ground selection driver GD2 through the second ground selection line GSL2.

In some implementations, the (n+1)-th to 2n-th word lines WLn+1 to WL2n may respectively correspond to the first to n-th word lines WL1 to WLn. In other words, the first to n-th word lines WL1 to WLn may respectively share the n word line drivers WDs with the (n+1)-th to 2n-th word lines WLn+1 to WL2n.

For example, the first word line WL1 may be connected to the (n+1)-th word line WLn+1 (in this case, this means that a wire configured to apply a voltage to a word line structure in the first sub-memory block sBLK1 and a wire configured to apply a voltage to a word line structure in the second sub-memory block sBLK2 are connected). That is, the first word line WL1 and the (n+1)-th word line WLn+1 may share a first word line driver. Also, the second word line WL2 may be connected to the (n+2)-th word line WLn+2. That is, the second word line WL2 and the (n+2)-th word line WLn+2 may share a second word line driver. As in the above description, the third to n-th word lines WL3 to WLn may be respectively connected to the (n+3)-th to 2n-th word lines WLn+3 to WL2n.

In this case, the first to n-th word lines WL1 to WLn and the (n+1)-th to 2n-th word lines WLn+1 to WL2n may be independent of each other in terms of a structure but may be referred as “the same word line” in terms of an applied voltage (i.e., in terms of a line). In other words, this means that the first sub-memory block sBLK1 and the second sub-memory block sBLK2 share the first to n-th word lines WL1 to WLn.

In some implementations, the first bit line BL1 may correspond to the second bit line BL2. In other words, the first bit line BL1 may share the page buffer PB with the second bit line BL2. For example, the first bit line BL1 and the second bit line BL2 may be connected (in this case, this means that a wire configured to apply a voltage to a bit line structure in the first sub-memory block sBLK1 and a wire configured to apply a voltage to a bit line structure in the second sub-memory block sBLK2 are connected).

In this case, the first bit line BL1 and the second bit line BL2 may be independent of each other in terms of a structure but may be referred as “the same bit line” in terms of an applied voltage (i.e., in terms of a line). In other words, this means that the first sub-memory block sBLK1 and the second sub-memory block sBLK2 share the first bit line BL1.

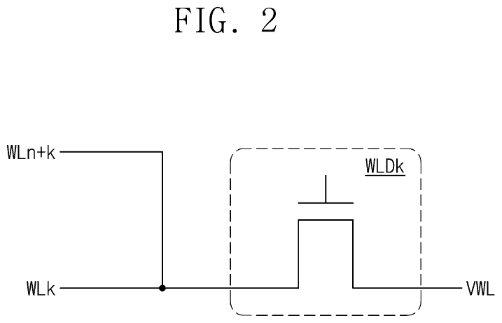

Each of the drivers may apply a voltage to a line connected thereto. This will be described in detail with reference to FIG. 2.

FIG. 2 is an example circuit diagram describing how the word line driver WD of FIG. 1 is shared. Referring to FIG. 2, the k-th word line driver WDk among the first to n-th word line drivers WDs is illustrated.

The word line driver WDk may include a drive transistor. The drive transistor may be provided with a word line voltage VWL from a voltage generator to be described later. When the drive transistor is turned on by a gate voltage, the word line voltage VWL is applied to each of the k-th word line WLk and the (n+k)-th word line WLn+k. The k-th word line WLk may be the k-th word line among the first to n-th word lines WL1 to WLn of FIG. 1. The (n+k)-th word line WLn+k may be the k-th word line among the (n+1)-th to 2n-th word lines WLn+1 to WL2n of FIG. 1.

In this case, the k-th word line WLk may be referred to as “sharing the word line driver WLDk with the (n+k)-th word line WLn+k”.

Although not illustrated, to share the page buffer PB of FIG. 1 and to share a common source driver to be described later will be described as in the above description.

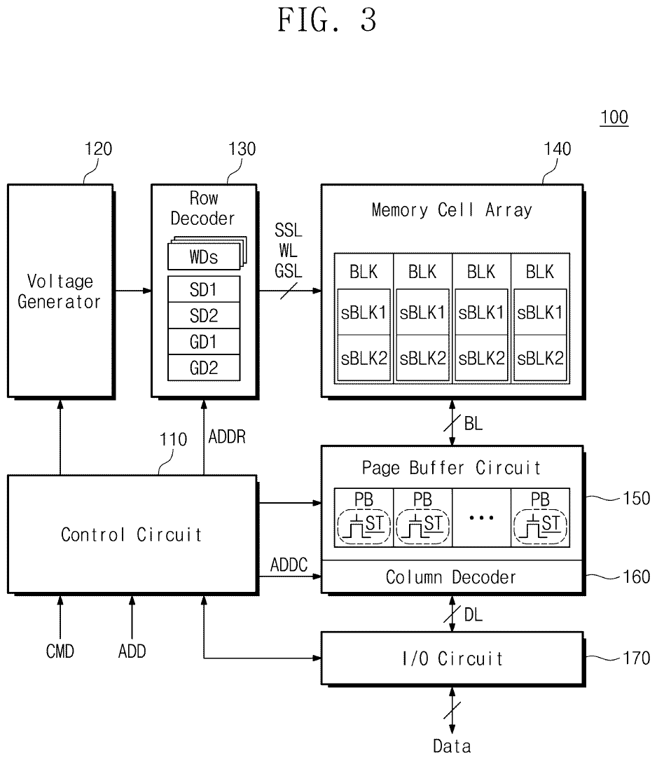

FIG. 3 is a block diagram of an example of the memory device 100. FIG. 4 is a circuit diagram illustrating an example of a first sub-memory block of FIG. 1 in detail. Referring to FIG. 3, the memory device 100 may include a control circuit 110, a voltage generator 120, a row decoder 130, a memory cell array 140, a page buffer circuit 150, a column decoder 160, and an input/output (I/O) circuit 170.

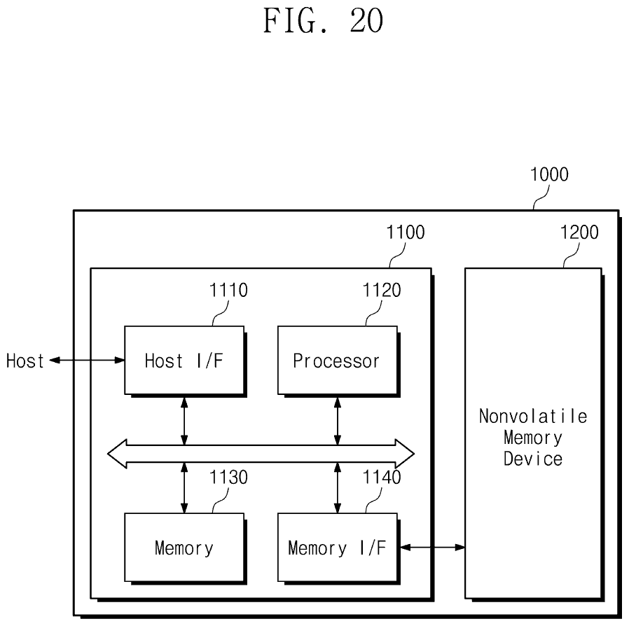

The control circuit 110 may receive a command CMD and an address ADD from a memory controller (i.e., a memory controller 1100 to be described with reference to FIG. 20). The command CMD may indicate the memory operation. The command CMD may refer to a signal indicating an operation to be performed by the memory device 100, such as a read operation, a write operation, or an erase operation. The address ADD may include a row address ADDR and a column address ADDC. The control circuit 110 may control all operations of the memory device 100 based on the command CMD and the address ADD. The control circuit 110 may generate the row address ADDR and the column address ADDC based on the address ADD.

Under control of the control circuit 110, the voltage generator 120 may control voltages to be applied to the memory cell array 140 through the row decoder 130.

The row decoder 130 may receive the row address ADDR from the control circuit 110. The row decoder 130 may be connected to the memory cell array 140 through string selection lines SSL, word lines WL, and ground selection lines GSL. The row decoder 130 may decode the row address ADDR and may control voltages to be applied to the string selection lines SSL, the word lines WL, and the ground selection lines GSL based on a decoding result and the voltages received from the voltage generator 120.

Also, the row decoder 130 may include the plurality of word line drivers WDs the first string selection driver SD1, the second string selection driver SD2, the first ground selection driver GD1, and the second ground selection driver GD2, which respectively correspond to the components with the same reference signs of FIG. 1.

The memory cell array 140 may include a plurality of memory blocks BLK. Each of the plurality of memory blocks BLK may be similar in structure to the memory block BLK illustrated in FIG. 1. The memory block BLK may include the first sub-memory block sBLK1 and the second sub-memory block sBLK2. The first sub-memory block sBLK1 may be included in a first wafer, and the second sub-memory block sBLK2 may be included in a second wafer. The memory block BLK may correspond to a physical erase unit of the memory device 100, but the present disclosure is not limited thereto. For example, the physical erase unit may be changed to a page unit, a word line unit, a sub-block unit, or the like.

Below, for convenience of description, a first direction D1, a second direction D2, and a third direction D3 are mentioned. The first direction D1 may be a direction parallel to a semiconductor substrate where the memory block BLK is formed. The second direction D2 may be a direction perpendicular to the first direction D1. The third direction D3 may be a direction that is perpendicular to a plane defined by the first direction D1 and the second direction D2. For example, the third direction D3 may be a direction perpendicular to the semiconductor substrate. The first direction D1, the second direction D2, and the third direction D3 may be referred to as a “row direction”, a “column direction”, and a “height direction”, respectively.

As illustrated in FIG. 4, the first sub-memory block sBLK1 may include a plurality of cell strings CS11, CS12, CS21, and CS22. The plurality of cell strings CS11, CS12, CS21, and CS22 may be arranged in the first direction D1 and the second direction D2. For brevity of drawing, four cell strings CS11, CS12, CS21, and CS22 are illustrated in FIG. 4, but the present disclosure is not limited thereto. For example, the number of cell strings may increase or decrease in the first direction D1 or the second direction D2.

Cell strings located at the same column from among the plurality of cell strings CS11, CS12, CS21, and CS22 may be connected to the same bit line. For example, the cell strings CS11 and CS21 may be connected to a bit line BL11, and the cell strings CS12 and CS22 may be connected to a bit line BL12. Each of the plurality of cell strings CS11, CS12, CS21, and CS22 includes a plurality of cell transistors. The plurality of cell transistors may be stacked in the third direction D3.

The plurality of cell transistors may be connected in series between the corresponding bit line (e.g., BL11 or BL12) and a first common source line CSL1. For example, the plurality of cell transistors may include a string selection transistor SST, memory cells MC1 to MC4, and a ground selection transistor GST. The string selection transistor SST may be provided between the serially-connected memory cells MC1 to MC4 and the corresponding bit line (e.g., BL11 and BL12). The ground selection transistor GST may be provided between the serially-connected memory cells MC1 to MC4 and the first common source line CSL1.

Memory cells located at the same height from among the memory cells MC1 to MC4 of the plurality of cell strings CS11, CS12, CS21, and CS22 may share the same word line. For example, the first memory cells MC1 of the plurality of cell strings CS11, CS12, CS21, and CS22 may be located at the same height from the semiconductor substrate and may share the first word line WL1. The second memory cells MC2 of the plurality of cell strings CS11, CS12, CS21, and CS22 may be located at the same height from the semiconductor substrate and may share the second word line WL2. Likewise, the third memory cells MC3 of the plurality of cell strings CS11, CS12, CS21, and CS22 may be located at the same height from the semiconductor substrate and may share the third word line WL3, and the fourth memory cells MC4 of the plurality of cell strings CS11, CS12, CS21, and CS22 may be located at the same height from the semiconductor substrate and may share the fourth word line WL4.

The string selection transistors SST of the plurality of cell strings CS11, CS12, CS21, and CS22 may be connected to the same string selection line. For example, the string selection transistors of the cell strings CS11 and CS12 may be connected to a string selection line SSL11, and the string selection transistors SST of the cell strings CS21 and CS22 may be connected to a string selection line SSL12.

Ground selection transistors located at the same height and the same row from among the ground selection transistors GST of the plurality of cell strings CS11, CS12, CS21, and CS22 may be connected to the same ground selection line. For example, the ground selection transistors GST of the cell strings CS11 and CS12 may be connected to a ground selection line GSL11, and the ground selection transistors GST of the cell strings CS21 and CS22 may be connected to a ground selection line GSL12.

The first sub-memory block sBLK1 illustrated the FIG. 4 is provided as only an example. For example, the number of cell strings may increase or decrease, and the number of rows of cell strings and the number of columns of cell strings may increase or decrease depending on the change in the number of cell strings. Also, in the memory block BLK, the number of cell transistors may increase or decrease, the height of the memory block BLK may increase or decrease depending on the number of cell transistors, and the number of lines connected with the cell transistors may increase or decrease depending on the number of cell transistors.

In some implementations, the memory block BLK may include a plurality of pages. For example, the first memory cells MC1 of the cell strings CS11, CS12, CS21, and CS22 connected with the first word line WL1 may be referred to as a “first physical page”.

In some implementations, one physical page may correspond to a plurality of logical pages. For example, when the first memory cell MC1 is a triple level cell (TLC) storing information corresponding to three bits, a physical page may correspond to three logical pages.

In some implementations, the memory block BLK of FIG. 3 has a structure in which the second sub-memory block sBLK2 having the same structure as the first sub-memory block sBLK1 is stacked on the first sub-memory block sBLK1 in the vertical direction.

Referring to FIGS. 3 and 4, the page buffer circuit 150 may include a plurality of page buffers PB. The page buffer circuit 150 may be connected to the memory cell array 140 through the bit lines BL. The page buffer circuit 150 may read data from the memory cell array 140 in units of page, by sensing voltages of the bit lines BL.

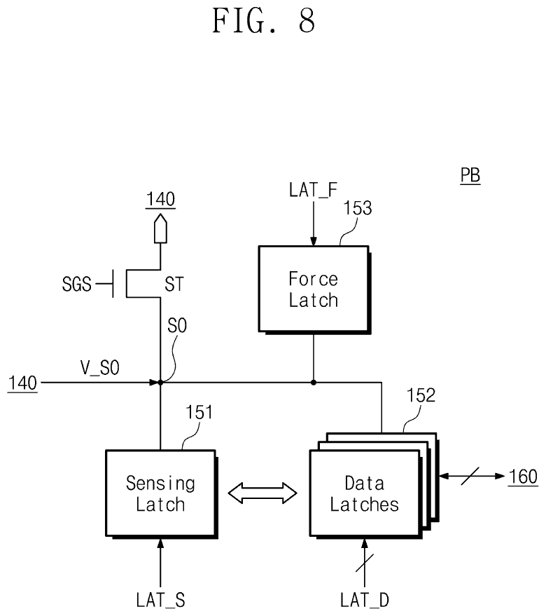

In some implementations, the page buffer PB may include a sensing transistor ST. This will be described in detail with reference to FIG. 8.

The column decoder 160 may receive the column address ADDC from the control circuit 110. The column decoder 160 may decode the column address ADDC and may provide the data read by the page buffer circuit 150 to the I/O circuit 170 based on a decoding result.

The column decoder 160 may receive data from the I/O circuit 170 through data lines DL. The column decoder 160 may receive the column address ADDC from the control circuit 110. The column decoder 160 may decode the column address ADDC and may provide the data received from the I/O circuit 170 to the page buffer circuit 150 based on a decoding result. The page buffer circuit 150 may store the data provided from the I/O circuit 170 in the memory cell array 140 through the bit lines BL in units of page.

The I/O circuit 170 may be connected to the column decoder 160 through the data lines DL. The I/O circuit 170 may transfer data received from the memory controller to the column decoder 160 through the data lines DL. The I/O circuit 170 may provide data received through data lines DL to the memory controller 1100.

In general, the memory operation for the first sub-memory block sBLK1 may be different from the memory operation for the second sub-memory block sBLK2. The reason is that the first wafer and the second wafer have different structural characteristics and different electrical characteristics in the producing process. Also, even though lines connected to the first wafer respectively correspond to lines connected to the second wafer, there may be a difference in the length of a wire connected to a driver. According to the above description, a speed of the memory operation for the first sub-memory block sBLK1 and a speed of the memory operation for the second sub-memory block sBLK2 may be different each other. For example, the speed of the memory operation for the first sub-memory block sBLK1 may be faster than the speed of the memory operation for the second sub-memory block sBLK2. As another example, loads of word lines and bit lines connected to the first sub-memory block sBLK1 may be smaller than loads of word lines and bit lines connected to the second sub-memory block sBLK2. In this case, the first sub-memory block sBLK1 may be referred to as a “fast block”, and the second sub-memory block sBLK2 may be referred to as a “slow block”.

In some implementations, a threshold voltage of a memory cell included in the fast block may be lower than a threshold voltage of a memory cell included in the slow block.

The memory device 100 according to the present disclosure may control the drivers and the page buffer PB to compensate for differences between the speed of the memory operation for the first sub-memory block sBLK1 and the speed of the memory operation for the second sub-memory block sBLK2 and between the loads of word lines and bit lines connected to the first sub-memory block sBLK1 and the loads of word lines and bit lines connected to the second sub-memory block sBLK2. The memory operation may indicate the program operation, the read operation (or verify operation), the erase operation, etc. For example, the memory device 100 may control the drivers and the page buffer PB through the control circuit 110.

In some implementations, the differences may be compensated for by adjusting a voltage magnitude and an application time of each of a first voltage which the control circuit 110 applies to the first sub-memory block sBLK1 and a second voltage which the control circuit 110 applies to the second sub-memory block sBLK2. The first voltage may indicate a voltage which is applied to one of lines connected to the first sub-memory block sBLK1. The second voltage may indicate a voltage which is applied to a line being one of lines connected to the second sub-memory block sBLK2 and corresponding to one of the lines connected to the first sub-memory block sBLK1. For example, the magnitude of the second voltage may be greater than the magnitude of the first voltage, and the application time of the second voltage may be longer than the application time of the first voltage.

In detail, when the memory operation on the first sub-memory block sBLK1 is performed, during a first target time, the control circuit 110 may control the drivers and the page buffer PB such that the first voltage is applied to a first target line among the lines connected to the first sub-memory block sBLK1. In this case, when the memory operation on the second sub-memory block sBLK2 is performed, the control circuit 110 may control the drivers and the page buffer PB such that one of the following three operations is performed. According to the first operation, the control circuit 110 may apply the first voltage to the second sub-memory block sBLK2 during a second target time longer than the first target time. According to the second operation, the control circuit 110 may apply the second voltage greater than the first voltage to the second sub-memory block sBLK2 during the first target time. According to the third operation, the control circuit 110 may apply the second voltage to the second sub-memory block sBLK2 during the second target time. The target time may indicate the length of a given time. The target line may indicate a line to which a voltage is applied. The second target line may be a line corresponding to the first target line.

For example, the first target line may be a first word line, and the second target line may be an (n+1)-th word line. The first target line may be a first bit line, and the second target line may be a second bit line. The first target line may be a first string selection line, and the second target line may be a second string selection line. The first target line may be a first ground selection line, and the second target line may be a second ground selection line. Alternatively, the first target line may be a first common source line to be described later, and the second target line may be a second common source line to be described later.

In some implementations, the control circuit 110 may include a random access memory (RAM). The RAM may store data associated with a first target voltage, a first target time, a second target voltage, and a second target time. The control circuit 110 may obtain data associated with the first target voltage and the second target voltage by referring to the RAM. The control circuit 110 may control the voltage generator 120 such that the voltage generator 120 generates the first target voltage and the second target voltage. The control circuit 110 may obtain data associated with the first target time and the second target time by referring to the RAM. The control circuit 110 may control the drivers and the page buffers PB based on the first target time and the second target time.

In addition, when the characteristic of the first wafer is opposite to the characteristic of the second wafer, the operations of the control circuit 110 associated with the first sub-memory block sBLK1 and the second sub-memory block sBLK2 may be opposite to each other.

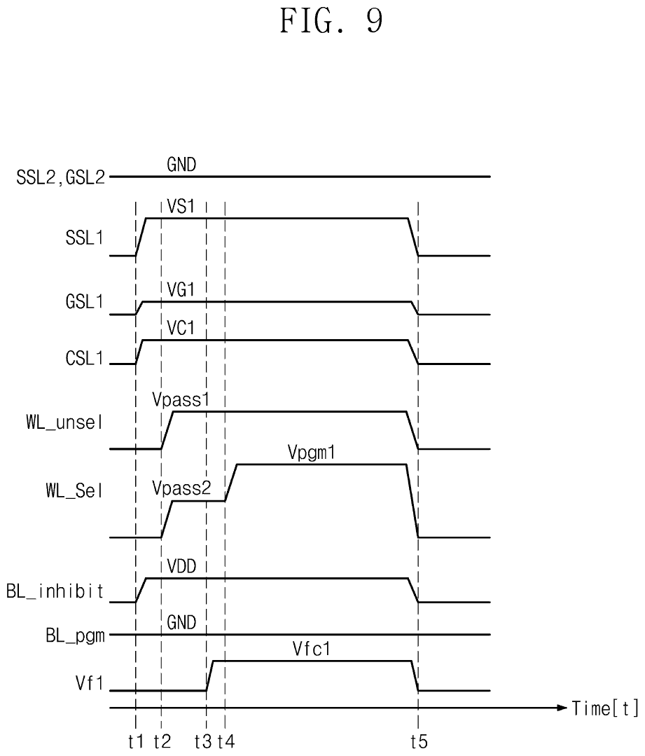

A detailed control method for each memory operation will be described in detail with reference to FIGS. 9 to 19.

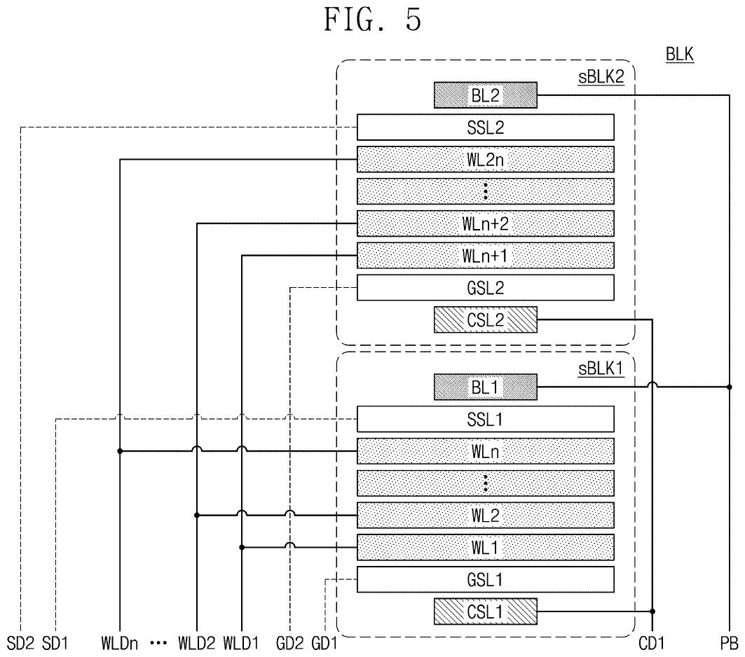

FIG. 5 is a diagram schematically illustrating an example of a cross section of the memory block BLK of FIG. 1. The vertical cross section of the memory block BLK of FIG. 1 taken along a direction perpendicular to the column direction is illustrated in FIG. 5.

The first to n-th word lines WL1 to WLn and the (n+1)-th to 2n-th word lines WLn+1 to WL2n may share the first to n-th word line drivers WD1 to WDn. The first bit line BL1 and the second bit line BL2 may share the page buffer PB. The first string selection line SSL1, the second string selection line SSL2, the first ground selection line GSL1, and the second ground selection line GSL2 may be respectively connected to the first string selection driver SD1, the second string selection driver SD2, the first ground selection driver GD1, and the second ground selection driver GD2. For convenience, the description which is given with reference to FIG. 1 will be omitted to avoid redundancy.

The first sub-memory block sBLK1 may further include the first common source line CSL1. The second sub-memory block sBLK2 may further include a second common source line CSL2.

In some implementations, the first common source line CSL1 and the second common source line CSL2 may share a first common source driver CD1. For example, the first common source line CSL1 and the second common source line CSL2 may be connected. In this case, the first common source line CSL1 and the second common source line CSL2 may be independent of each in terms of a structure but may be considered as being identical in terms of an applied voltage (i.e., in terms of a wire). In other words, the first sub-memory block sBLK1 and the second sub-memory block sBLK2 may share the first common source line CSL1.

The memory device 100 may apply a voltage to the first sub-memory block sBLK1 and the second sub-memory block sBLK2 through the first common source driver CD1 and the first common source line CSL1.

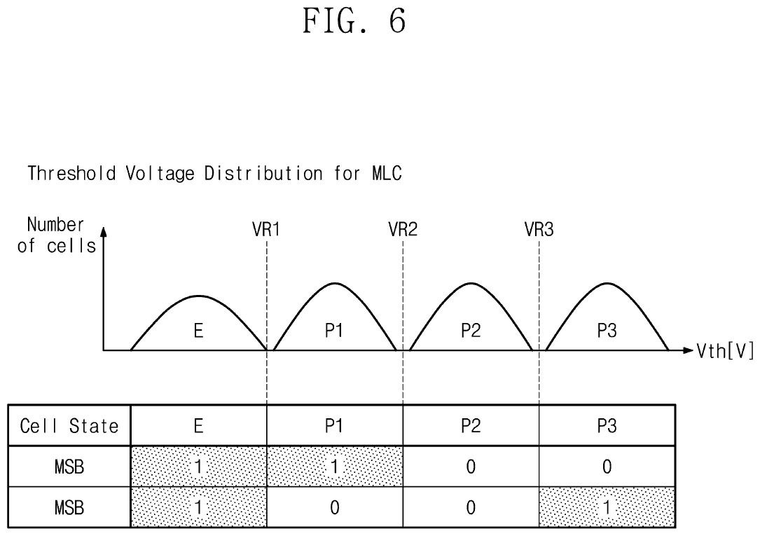

FIG. 6 is a diagram describing example threshold voltage distributions of memory cell. A graph of threshold voltage distributions of multi-level cells (MCLs) each storing two bits and a page-specific bit table corresponding to the threshold voltage distributions are illustrated in FIG. 6. Below, for convenience of description, the multi-level cell MLC is intended to refer to a memory cell storing two bits, a memory cell storing three bits is referred to as a “triple level cell TLC”, and a memory cell storing four bits is referred to as a “quadruple level cell QLC”.

Referring to the graph of the multi-level cells MLC, the horizontal axis represents a threshold voltage (e.g., a level of a threshold voltage), and the vertical axis represents the number of memory cells. The multi-level cell MLC may have one of an erase state “E” and first to third program states P1, P2, and P3 whose threshold voltage distributions sequentially increase.

In the multi-level cell MLC, a first read voltage level VR1 may refer to a voltage for distinguishing the erase state “E” from the first program state P1. A second read voltage level VR2 may refer to a voltage for distinguishing the first program state P1 from the second program state P2. A third read voltage level VR3 may refer to a voltage for distinguishing the second program state P2 from the third program state P3.

The table of the multi-level cell MLC shows a least significant bit LSB and a most significant bit MSB for each cell state. A physical page corresponding to the multi-level cell MCL storing two bits may correspond to first and second logical pages. In the multi-level cell MLC, the first logical page may indicate the least significant bit LSB, and the second logical page may indicate the most significant bit MSB.

In some implementations, each of the first to third read voltage levels VR1 to VR3 of the multi-level cell MLC may correspond to one of a plurality of logical pages. For example, in the multi-level cell MLC, the read operation corresponding to the first logical page may be performed based on the second read voltage level VR2. The read operation corresponding to the second logical page may be performed based on the first read voltage level VR1 and the third read voltage level VR3.

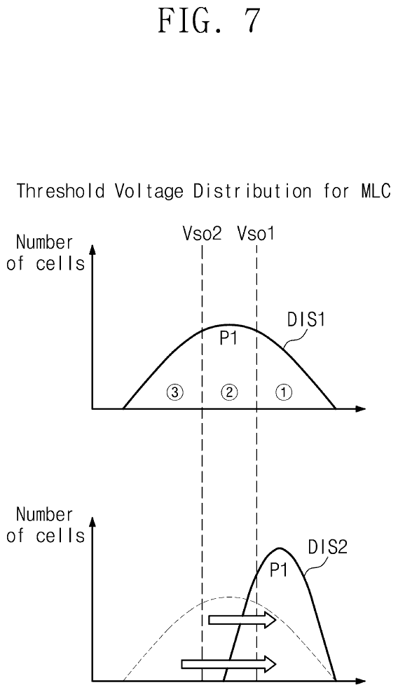

FIG. 7 is a diagram describing an example of a method of adjusting a threshold voltage distribution of memory cells. An operation of adjusting a threshold voltage distribution of memory cells such that a breadth width becomes narrower will be described with reference to FIG. 7.

The breadth width of the threshold voltage distribution (i.e., a threshold voltage magnitude range) may become wider than an initial breadth width due to various factors. For example, the breadth width of the threshold voltage distribution may gradually become wider over time or depending on the number of times that operations are repeated.

When the breadth width of the threshold voltage distribution becomes wider, the threshold voltage distribution may partially overlap a threshold voltage distribution having any other cell state. According to the above description, the performance of the program operation, the read operation (including verify operations), and the erase operation may be degraded. For this reason, there is a need to apply a scheme of narrowing the breadth width of the threshold voltage distribution (e.g., a scheme of using a force latch 153 (refer to FIG. 8) of the page buffer PB) whenever a given operation is performed or periodically.

As the simplest example, a memory device may perform the above scheme by using two sensing voltages (i.e., read voltages or verify voltages) Vso1 and Vso2. Each of the first sensing voltage Vso1 and the second sensing voltage Vso2 may be generated depending on an operation of a sensing transistor in a page buffer to be described later. In addition, the memory device may perform the above scheme by using three or more sensing voltages.

The memory device may classify memory cells included in a first distribution DIS1 into three groups by using the first sensing voltage Vso1 and the second sensing voltage Vso2.

Threshold voltages of memory cells included in a first group \textcircled{1} are greater than the first sensing voltage Vso1. Threshold voltages of memory cells included in a second group \textcircled{2} are greater than the second sensing voltage Vso2 and smaller than the first sensing voltage Vso1. Threshold voltages of memory cells included in a third group \textcircled{3} are smaller than the second sensing voltage Vso2.

The memory device may apply a first program voltage to word lines of the memory cells included in the second group \textcircled{2}. The memory device may apply a second program voltage to word lines of the memory cells included in the third group \textcircled{3}. The second program voltage is greater than the first program voltage. According to the above description, the first distribution D1 may be adjusted to a second distribution DIS2 whose breadth width is narrower than that of the first distribution D1.

FIG. 8 is a diagram illustrating an example of the page buffer PB of FIG. 3 in detail. Referring to FIG. 8, the page buffer PB may include a sensing latch 151, a plurality of data latches 152, and the force latch 153.

The sensing latch 151 may store a sensing result. In the read operation or the program verify operation, the sensing result may be a value obtained by sensing data stored in a memory cell or a threshold voltage of the memory cell. In the program operation, the sensing latch 151 may be utilized to apply a program bit line voltage or a program-inhibit voltage to a bit line.

The sensing latch 151 may determine data of a cell string connected through the bit line in response to a sensing latch signal LAT_S. A level of a sensing node SO may change based on a voltage applied to transistors in the plurality of cell strings CS11, CS12, CS21, and CS22 of FIG. 4. In some implementations, the sensing latch signal LAT_S may be generated based on a page buffer control signal received from the control circuit 110.

In some implementations, the sensing latch 151 may determine the data of the connected cell string based on a current level of the sensing node SO. For example, the sensing latch 151 may determine the data of the connected cell string or may verify a program state of a selected memory cell, by comparing a level of a current flowing from the sensing node SO to the bit line through the cell string with a reference current level.

The plurality of data latches 152 may store program data received from the outside in the program operation. The plurality of data latches 152 may temporarily store the data received from the sensing latch 151. In some implementations, the number of data latches of the data latches 152 may be based on a kind of memory cells of a memory cell array. For example, when the memory cells MC1 to MC4 are triple level cells (TLC), the data latches 152 may include three individual data latches.

In some implementations, the plurality of data latches 152 may provide the stored data to the I/O circuit 170 through the data lines DL in response to a data latch signal LAT_D. The data latch signal LAT_D may be generated based on the page buffer control signal. In some implementations, in response to the data latch signal LAT_D, the data latches 152 may receive data to be stored or may receive data corresponding to a program state of a memory cell to be verified from the I/O circuit 170.

The force latch 153 may be used to improve a threshold voltage distribution in the program operation. A value of the force latch 153 may be changed depending on a threshold voltage of a memory cell during the program operation, and a bit line voltage may be varied depending on the value of the force latch 153 during the program operation. This will be more described in detail later.

The page buffer PB may include the sensing transistor ST controlling the connection of the bit line connected to the memory cell array 140 with the sensing latch 151 and the plurality of data latches 152. For example, when the data are read from the memory cell, the sensing transistor ST is turned on to electrically connect the bit line and the sensing latch 151. Also, when the data stored in the sensing latch 151 are transferred to the force latch 153, the sensing transistor ST may be turned off.

Also, to improve the program threshold voltage distribution, information about the program threshold voltage of the corresponding memory cell may be stored in the force latch 153. Force data capable of determining whether to apply a force voltage to the bit line during the program operation may be stored in the force latch 153.

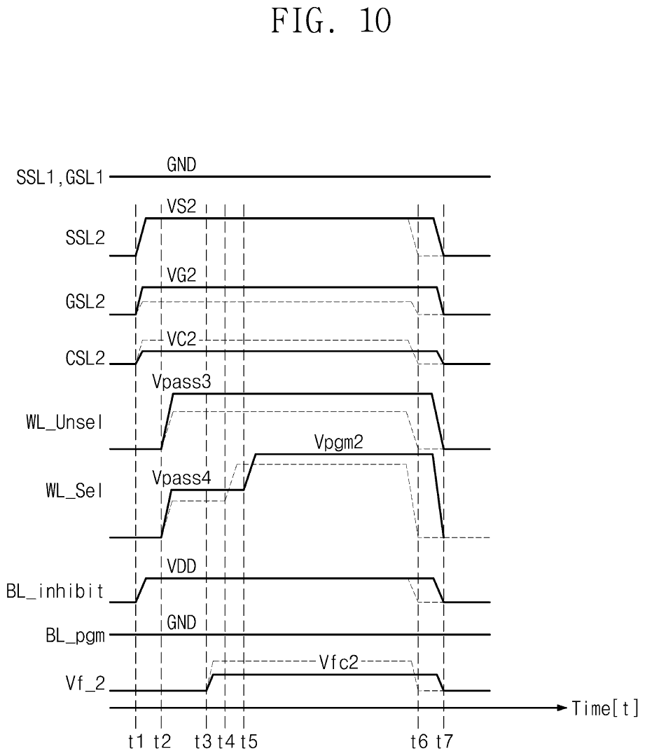

FIG. 9 is a timing diagram describing an example of a program operation on a first wafer. FIG. 10 is a timing diagram describing an example of a program operation on a second wafer. Referring to FIG. 9, changes in voltages associated with the program operation on a page in a first sub-memory block of a first wafer are illustrated over time. Referring to FIG. 10, changes in voltages associated with the program operation on a page in a second sub-memory block of a second wafer are illustrated over time. Below, the program operation may correspond to program execution in a normal program loop.

In FIGS. 9 and 10, the horizontal axis represents a time, and the vertical axis indicates a magnitude of a voltage.

Referring to FIGS. 9 and 10, when a memory device according to some implementations of the present disclosure performs a first program operation on a first sub-memory block and a second program operation on a second sub-memory block, respectively, the memory device may differently set a voltage magnitude of at least one of a force voltage and voltages, which are applied to an unselected word line WL_unsel, a selected word line WL_sel, a string selection line SSL, a ground selection line GSL, a common source line CSL, and an inhibit bit line BL_inhibit associated with each program operation, or an application time, for each of the first program operation and the second program operation.

The selected word line WL_sel may indicate a word line connected to a page targeted for the program operation from among first to n-th word lines. The unselected word line WL_unsel may indicate each of the remaining word lines among the first to n-th word lines other than the selected word line WL_sel.

The inhibit bit line BL_inhibit may be one of bit lines connected to the first sub-memory block and the second sub-memory block. The inhibit bit line BL_inhibit may indicate a bit line not connected to a string including a memory cell where the program operation is being performed. The voltage which is applied to the inhibit bit line BL_inhibit may be refer to as a “bit line inhibit voltage”.

The force voltage will be described in detail below. In some implementations, to program memory cells to different program states by using the same program pulse, different voltages may be applied to bit lines connected to memory cells to be programmed to different program states while the program pulse is being applied. A threshold voltage of a memory cell of the memory device may change by forcing a bit line with a given small voltage level, not a ground voltage GND.

In some implementations, when data stored in the force latch of the page buffer corresponds to the application of the force voltage to the bit line, the force voltage may be applied to the bit line.

As described above with respect to FIG. 3, the control circuit 110 may obtain information about the voltage magnitudes of the voltages or the application time by referring to the RAM. In other words, the control circuit 110 may obtain a plurality of voltage magnitudes or a plurality of application times, which are set in advance, by referring to the RAM. In this case, a command may be received from the memory controller and may indicate the memory operation (e.g., the first program operation or the second program operation).

Components illustrated in FIGS. 9 and 10 respectively correspond to components having the same reference signs in the above drawings.

As described above, the program operation is performed in units of page. Accordingly, the first program operation and the second program operation may be respectively performed in time periods not overlapping each other.

First, referring to FIG. 9, there is illustrated a timing diagram corresponding to the case where the first program operation on a page in the first sub-memory block is performed. In this case, the first sub-memory block is a selected sub-memory block, and the second sub-memory block is an unselected sub-memory block.

A voltage (e.g., the ground voltage GND) for turning off a second string selection transistor may be applied to the second string selection line SSL2 such that the program operation on the second sub-memory block is not performed. A voltage (e.g., the ground voltage GND) for turning off a second ground selection transistor may be applied to the second ground selection line GSL2.

The first program operation on the first sub-memory block may include applying a first voltage to a first target line connected to the first sub-memory block during a first target time.

In some implementations, the first target line may be one of the first string selection line SSL1, the first ground selection line GSL1, the selected word line WL_sel among the first to n-th word lines, the unselected word line WL_unsel among the first to n-th word lines, and the inhibit bit line BL_inhibit.

For example, referring to FIG. 9, the timing diagram from a first time point t1 to a fifth time point t5 is illustrated. The chronological order of the first to fifth time points t1 to t5 is as follows: the first time point t1, the second time point t2, the third time point t3, the fourth time point t4, and the fifth time point t5.

From the first time point t1 to the fifth time point t5, a first string selection voltage VS1 may be applied to the first string selection line SSL1. The first string selection voltage VS1 may be a voltage for turning on a string selection transistor connected to the first string selection line SSL1. From the first time point t1 to the fifth time point t5, a first ground selection voltage VG1 may be applied to the first ground selection line GSL1. The first ground selection voltage VG1 may be a voltage for turning on a ground selection transistor connected to the first ground selection line GSL1. From the first time point t1 to the fifth time point t5, a first common source voltage VC1 may be applied to the first common source line CSL1.

A voltage which is applied to the unselected word line WL_unsel is as follows. First, from the first time point t1 to the second time point t2, the ground voltage GND is applied to the unselected word line WL_unsel. From the second time point t2 to the fifth time point t5, a first pass voltage Vpass1 is applied to the unselected word line WL_unsel.

A voltage which is applied to the selected word line WL_sel is as follows. First, from the first time point t1 to the second time point t2, the ground voltage GND is applied to the selected word line WL_sel. From the second time point t2 to the fourth time point t4, a second pass voltage Vpass2 is applied to the selected word line WL_sel. From the fourth time point t4 to the fifth time point t5, a first program voltage Vpgm1 is applied to the selected word line WL_sel. In general, a program method in which a program voltage applied to a selected word line uniformly increases while a program loop progresses is called an incremental step pulse program method.

From the first time point t1 to the fifth time point t5, a power supply voltage VDD is applied to the inhibit bit line BL_inhibit.

From the first time point t1 to the fifth time point t5, the ground voltage GND is applied to a program bit line BL_pgm. The program bit line BL_pgm may indicate a bit line connected to a string selection line to which a memory cell to be programmed is connected. For example, the program bit line BL_pgm is a first bit line.

A change in a first force voltage Vf1 over time is as follows. From the first time point t1 to the third time point t3, the first force voltage Vf1 is the ground voltage GND. From the third time point t3 to the fifth time point t5, the first force voltage Vfc1 may be a first force voltage Vfc1.

Next, referring to FIG. 10, there is illustrated a timing diagram corresponding to the case where the second program operation on a page in the second sub-memory block is performed. In this case, the first sub-memory block is an unselected sub-memory block, and the second sub-memory block is a selected sub-memory block.

A voltage (e.g., the ground voltage GND) for turning off a first string selection transistor may be applied to the first string selection line SSL1 such that the program operation on the first sub-memory block is not performed. A voltage (e.g., the ground voltage GND) for turning off a first ground selection transistor may be applied to the first ground selection line GSL1.

In some implementations the second program operation on the second sub-memory block may include applying the first voltage to a second target line connected to the second sub-memory block during a second target time longer than the first target time. The second target line may correspond to the first target line. In other words, application times of some voltages applied to the second sub-memory block in the second program operation may be longer than the application times of the corresponding voltages applied to the first sub-memory block in the first program operation.

For example, referring to FIG. 10, changes of voltages from a first time point t1 to a sixth time point t6 are illustrated. The chronological order of the first to sixth time points t1 to t6 is as follows: the first time point t1, the second time point t2, the third time point t3, the fourth time point t4, the fifth time point t5, and the sixth time point t6. The first to fourth time points t1 to t4 and the sixth time point t6 respectively correspond to the first to fifth time points t1 to t5 of FIG. 9. However, timing diagrams are illustrated to overlap each other only to compare voltages set in the first program operation and voltages set in the second program operation, and the first program operation and the second program operation are independently performed in time periods not overlapping each other. In FIG. 10, voltages corresponding to the first program operation are marked by a dotted line.

From the first time point t1 to a seventh time point t7, a second string selection voltage VS2 may be applied to the second string selection line SSL2. The magnitude of the second string selection voltage VS2 may be identical to the magnitude of the first string selection voltage VS1.

From the first time point t1 to the seventh time point t7, the power supply voltage VDD is applied to the inhibit bit line BL_inhibit.

Although not illustrated, from the first time point t1 to the seventh time point t7, the first ground selection voltage VG1 may be applied to the second ground selection line GSL2.

Although not illustrated, the ground voltage GND may be applied to the unselected word line WL_unsel from the first time point t1 to the second time point t2, and the first pass voltage Vpass1 may be applied to the unselected word line WL_unsel from the second time point t2 to the seventh time point t7.

Although not illustrated, the ground voltage GND may be applied to the selected word line WL_sel from the first time point t1 to the second time point t2, the second pass voltage Vpass2 may be applied to the selected word line WL_sel from the second time point t2 to the fifth time point t5, and the first program voltage Vpgm1 may be applied to the selected word line WL_sel from the fifth time point t5 to the seventh time point t7.

Although not illustrated, a second force voltage Vf_2 may be the ground voltage GND from the first time point t1 to the third time point t3 and may be the first force voltage Vfc1 from the third time point t3 to the seventh time point t7.

In some implementations, although not illustrated, in the second program operation on the second sub-memory block, the second voltage greater than the first voltage may be applied to the second target line during the first target time. In other words, magnitudes of some voltages applied to the second sub-memory block in the second program operation may be greater than the magnitudes of the corresponding voltages applied to the first sub-memory block in the first program operation.

Although not illustrated, a second ground selection voltage VG2 greater than the first ground selection voltage VG1 may be applied to the second ground selection line GSL2 from the first time point t1 to the sixth time point t6, and the ground voltage GND may be applied to the second ground selection line GSL2 from the sixth time point t6.

Although not illustrated, a third pass voltage Vpass3 greater than the first pass voltage Vpass1 may be applied to the unselected word line WL_unsel from the first time point t1 to the sixth time point t6, and the ground voltage GND may be applied to the unselected word line WL_unsel from the sixth time point t6.

Although not illustrated, a fourth pass voltage Vpass4 greater than the second pass voltage Vpass2 may be applied to the selected word line WL_sel from the first time point t1 to the fourth time point t4, a second program voltage Vpgm2 greater than the first program voltage Vpgm1 may be applied to the selected word line WL_sel from the fourth time point t4 to the sixth time point t6, and the ground voltage GND may be applied to the selected word line WL_sel from the sixth time point t6.

In some implementations, in the second program operation on the second sub-memory block, the second voltage may be applied to the second target line during the second target time. In other words, magnitudes and application times of some voltages applied to the second sub-memory block in the second program operation may be greater (or longer) than the magnitudes and the application times of the corresponding voltages applied to the first sub-memory block in the first program operation.

Although not illustrated, from the first time point t1 to the seventh time point t7, the first ground selection voltage VG1 may be applied to the second ground selection line GSL2.

The ground voltage GND may be applied to the unselected word line WL_unsel from the first time point t1 to the second time point t2, and the third pass voltage Vpass3 greater than the first pass voltage Vpass1 may be applied to the unselected word line WL_unsel from the second time point t2 to the seventh time point t7.

The ground voltage GND may be applied to the selected word line WL_sel from the first time point t1 to the second time point t2, the fourth pass voltage Vpass4 greater than the second pass voltage Vpass2 may be applied to the selected word line WL_sel from the second time point t2 to the fifth time point t5, and the second program voltage Vpgm2 greater than the first program voltage Vpgm1 may be applied to the selected word line WL_sel from the fifth time point t5 to the seventh time point t7.

According to the above description, a difference between a speed of the first program operation and a speed of the second program operation may decrease. For example, the speed of the second program operation corresponding to the slow block may be quickly adjusted.

However, as the magnitude of the voltage applied to the common source line and the magnitude of the force voltage become greater during each program operation, the program operation speed decreases.

Accordingly, from the first time point t1 to the seventh time point t7, a second common source voltage VC2 smaller than the first common source voltage VC1 may be applied to the second common source line CSL2.

Also, the second force voltage Vf_2 may be the ground voltage GND from the first time point t1 to the third time point t3 and may be a second force voltage Vfc2 smaller than the first force voltage Vfc1 from the third time point t3 to the seventh time point t7.

In some implementations, the first common source line CSL1 and the second common source line CSL2 may share the first common source driver CD1. However, the present disclosure is not limited thereto. As will be described later, even when the first common source line CSL1 and the second common source line CSL2 are respectively connected to the first common source driver CD1 and a second common source driver CD2, the program operation may be performed to be identical to the above description.

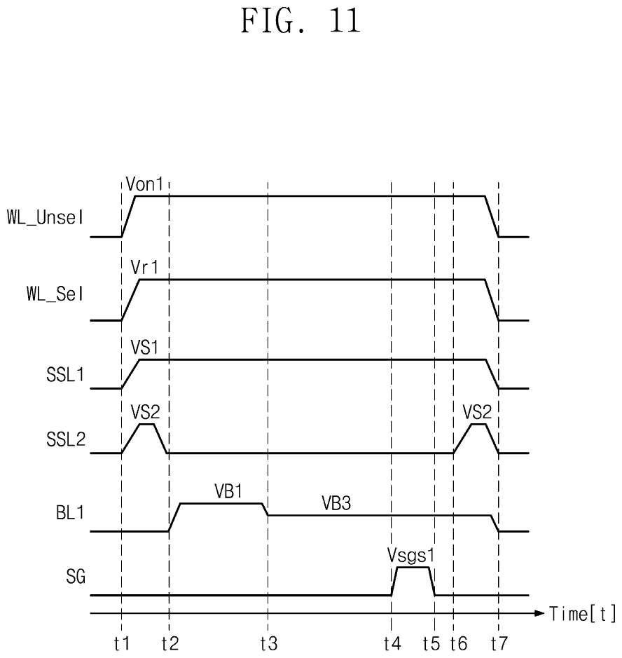

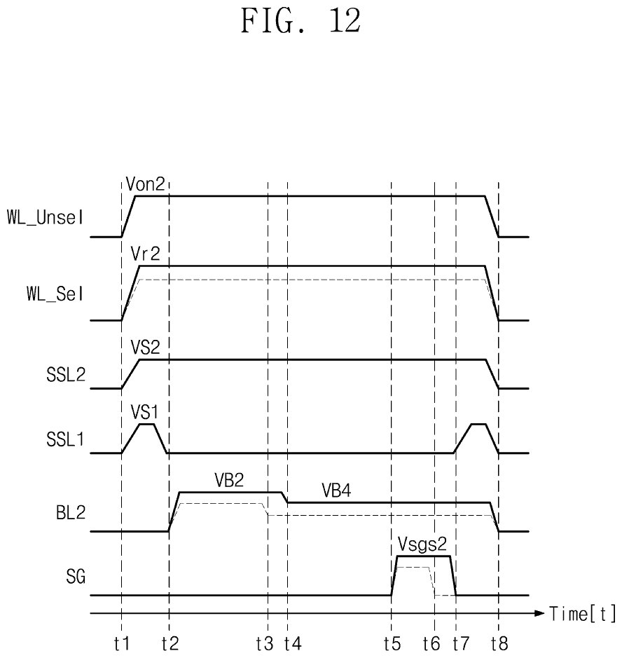

FIG. 11 is a timing diagram describing an example of a read operation on a first wafer. FIG. 12 is a timing diagram describing an example of a read operation on a second wafer. Referring to FIG. 11, changes in voltages associated with a first read operation on a first sub-memory block of a first wafer are illustrated over time. Referring to FIG. 12, changes in voltages associated with a second read operation on a second sub-memory block of a second wafer are illustrated over time.

In FIGS. 11 and 12, the horizontal axis represents a time, and the vertical axis indicates a magnitude of a voltage.

Referring to FIGS. 11 and 12, when a memory device according to some implementations of the present disclosure performs the first read operation on the first sub-memory block and the second read operation on the second sub-memory block, respectively, the memory device may differently set a voltage magnitude or an application time of at least one of voltages, which are applied to the selected word line WL_sel and the bit line BL associated with each read operation, and a voltage applied to a sensing transistor gate SG, for each of the first read operation and the second read operation.

The selected word line WL_sel may indicate a word line connected to a page targeted for the read operation from among the first to n-th word lines. The unselected word line WL_unsel may indicate each of the remaining word lines among the first to n-th word lines other than the selected word line WL_sel.

Components illustrated in FIGS. 11 and 12 respectively correspond to components having the same reference signs in the above drawings.

As described above, the read operation is performed in units of page. Accordingly, the first read operation and the second read operation may be respectively performed in time periods not overlapping each other.

First, referring to FIG. 11, there is illustrated a timing diagram corresponding to the case where the first read operation on a page in the first sub-memory block is performed. In this case, the first sub-memory block is a selected sub-memory block, and the second sub-memory block is an unselected sub-memory block.

For example, referring to FIG. 11, the timing diagram from the first time point t1 to the seventh time point t7 is illustrated. The chronological order of the first to seventh time points t1 to t7 is as follows: the first time point t1, the second time point t2, the third time point t3, the fourth time point t4, the fifth time point t5, the sixth time point t6, and the seventh time point t7.

In this case, during a given time, the ground voltage GND may be applied to the second string selection line SSL2 such that the read operation on the second sub-memory block is not performed. For example, the second string selection voltage VS2 may be applied to the second string selection line SSL2 from the first time point t1 to the second time point t2, the ground voltage GND may be applied to the second string selection line SSL2 from the second time point t2 to the sixth time point t6, and the second string selection voltage VS2 may be applied to the second string selection line SSL2 from the sixth time point t6 to the seventh time point t7. In the read operation, voltage sensing may be performed between the second time point t2 and the sixth time point t6. In other words, while voltage sensing is performed in the read operation, the second string selection transistor connected to the second string selection line SSL2 may be turned off.

The first read operation may include applying a first read voltage Vr1 to the selected word line WL_sel from the first time point t1 to the seventh time point t7.

The first read operation may include applying a first bit line voltage VB1 to the first bit line BL1 from the second time point t2 to the third time point t3. From the third time point t3 to the seventh time point t7, a third bit line voltage VB3 may be applied to the first bit line BL1.

The first read operation may include applying a first sensing gate voltage Vsgs1 to the sensing transistor gate SG from the fourth time point t4 to the fifth time point t5. In other words, from the fourth time point t4 to the sixth time point t6, data stored in the memory cell may be determined based on a current sensed at the sensing node.

In addition, from the first time point t1 to the seventh time point t7, a first turn-on voltage Von1 may be applied to the unselected word line WL_unsel. The first turn-on voltage Von1 may be higher than a threshold voltage of a memory cell connected to the unselected word line WL_unsel (i.e., a threshold voltage of a memory cell targeted for the read operation). From the first time point t1 to the seventh time point t7, the first string selection voltage VS1 may be applied to the first string selection line SSL1. From the first time point t1 to the second time point t2, the ground voltage GND may be applied to the first bit line BL1. Before the fourth time point t4 and after the fifth time point t5, the ground voltage GND may be applied to the gate SG of the sensing transistor.

Next, referring to FIG. 12, there is illustrated a timing diagram corresponding to the case where the second read operation on a page in the second sub-memory block is performed. In this case, the first sub-memory block is an unselected sub-memory block, and the second sub-memory block is a selected sub-memory block.

For example, referring to FIG. 12, changes of voltages from a first time point t1 to an eighth time point t8 are illustrated. The chronological order of the first to eighth time points t1 to t8 is as follows: the first time point t1, the second time point t2, the third time point t3, the fourth time point t4, the fifth time point t5, the sixth time point t6, the seventh time point t7, and the eighth time point t8. The first to fourth time points t1 to t4 and the sixth time point t6 respectively correspond to the first to fifth time points t1 to t5 of FIG. 9. However, timing diagrams are illustrated to overlap each other only to compare voltages set in the first program operation and voltages set in the second program operation, and the first program operation and the second program operation are independently performed in time periods not overlapping each other. In FIG. 12, voltages corresponding to the first program operation are marked by a dotted line. The first to third time points t1 to t3 and the fifth to eighth time points t5 to t8 respectively correspond to the first to seventh time points t1 to t7 of FIG. 11. However, timing diagrams are illustrated to overlap each other only to compare voltages set in the first read operation and voltages set in the second read operation, and the first read operation and the second read operation are independently performed in time periods not overlapping each other. In FIG. 12, voltages corresponding to the first read operation are marked by a dotted line.

In this case, during a given time, the ground voltage GND may be applied to the first string selection line SSL1 such that the read operation on the first sub-memory block is not performed. For example, the first string selection voltage VS1 may be applied to the first string selection line SSL1 from the first time point t1 to the second time point t2, the ground voltage GND may be applied to the first string selection line SSL1 from the second time point t2 to the seventh time point t7, and the first string selection voltage VS1 may be applied to the first string selection line SSL1 from the seventh time point t7 to the eighth time point t8. In the read operation, voltage sensing may be performed between the second time point t2 and the seventh time point t7. In other words, while voltage sensing is performed in the read operation, the first string selection transistor connected to the first string selection line SSL1 may be turned off.

The second read operation may include applying a second read voltage Vr2 to the selected word line WL_sel from the first time point t1 to the seventh time point t7.

The second read operation may include one of the following three operations. First, although not illustrated, the first bit line voltage VB1 may be applied to the second bit line BL2 from the second time point t2 to the fourth time point t4. Alternatively, although not illustrated, a second bit line voltage VB2 greater than the first bit line voltage VB1 may be applied to the second bit line BL2 from the second time point t2 to the third time point t3. Alternatively, the second bit line voltage VB2 may be applied to the second bit line BL2 from the second time point t2 to the fourth time point t4.

The second read operation may include one of the following three operations. First, although not illustrated, the first sensing gate voltage Vsgs1 may be applied to the sensing transistor gate SG from the fifth time point t5 to the seventh time point t7. Alternatively, although not illustrated, a second sensing gate voltage Vsgs2 greater than the first sensing gate voltage Vsgs1 may be applied to the sensing transistor gate SG from the fifth time point t5 to the sixth time point t6. The second sensing gate voltage Vsgs2 may be applied to the sensing transistor gate SG from the fifth time point t5 to the seventh time point t7.

In addition, from the first time point t1 to the eighth time point t8, a second turn-on voltage Von2 may be applied to the unselected word line WL_unsel. For example, the second turn-on voltage Von2 may be the same as the first turn-on voltage Von1. From the first time point t1 to the eighth time point t8, the second string selection voltage VS2 may be applied to the second string selection line SSL2. From the first time point t1 to the second time point t2, the ground voltage GND may be applied to the second bit line BL2. Before the fifth time point t5 and after the seventh time point t7, the ground voltage GND may be applied to the sensing transistor gate SG.

According to the above description, the memory device according to the present disclosure may reduce a difference between a load of a first word line associated with the first read operation and a load of a second word line associated with the first read operation and a difference between a load of the first bit line BL1 associated with the first read operation and a load of the second bit line BL2 associated with the second read operation. In other words, the memory device may compensate for a characteristic difference of the first read operation and the second read operation.

In some implementations, the above read operation may indicate the verify operation. For example, the verify operation may indicate an erase verify operation of determining whether memory cells are in the erase state, after the erase operation of the erase sequence. As another example, the verify operation may indicate a program verify operation of determining whether memory cells have a cell state to be programmed, after the program operation.

In some implementations, although not illustrated, sensing may be further performed by using any other verify voltages between the fourth time point t4 and the fifth time point t5 (between the third time point t3 and the fourth time point t4 in FIG. 11). In other words, the verify operation may perform sensing by using two verify voltages with different voltage levels two times. However, the present disclosure is not limited thereto. For example, sensing may be performed three times or more. That is, the read operation (or the verify operation) may be performed based on three or more different verify voltages.

For example, the sensing transistor may be turned on from the fifth time point t5 to the sixth time point t6, and thus, a first verify voltage of the first sensing may be determined. The sensing transistor may be turned on during a given time period from the fourth time point t4 to the fifth time point t5, and thus, a second verify voltage of the second sensing may be determined. In detail, the length of the given time period from the fourth time point t4 to the fifth time point t5 may be shorter than the length of a time period from the fifth time point t5 to the sixth time point t6. In other words, the level of the second verify voltage may be higher than the level of the first verify voltage.

In detail, as in the first sensing described above, in the second sensing, the first verify operation may include applying the first sensing gate voltage Vsgs1 to the gate of the sensing transistor during a third target time. The second verify operation may include one of applying the first sensing gate voltage Vsgs1 to the gate of the sensing transistor during a fourth target time longer than a third target time, applying the second sensing gate voltage Vsgs2 greater than the first sensing gate voltage Vsgs1 to the gate of the sensing transistor during the third target period, and applying the second sensing gate voltage Vsgs2 to the gate of the sensing transistor during the fourth target period.

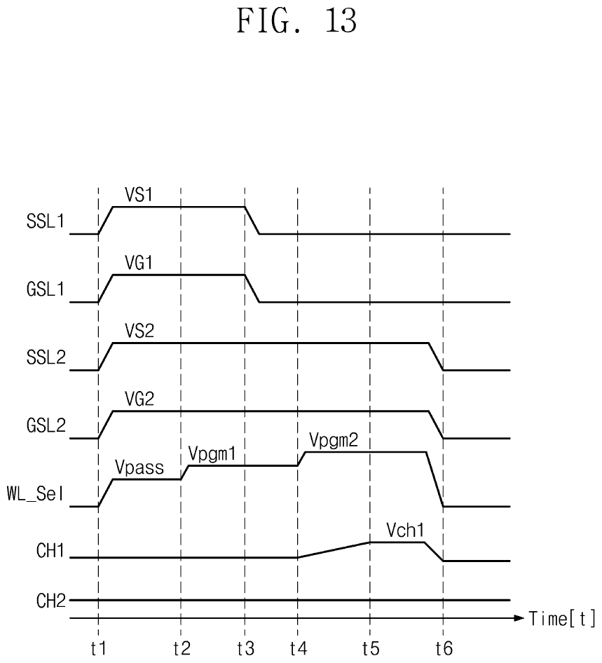

FIG. 13 is a timing diagram describing an example of a pre-program operation in an erase sequence of a memory block. Referring to FIG. 13, there are illustrated changes in voltages associated with a pre-program operation over time when the first common source line CSL1 and the second common source line CSL2 are connected to the first common source driver. In FIG. 13, the horizontal axis represents a time, and the vertical axis represents a magnitude of a voltage.

The erase sequence may be performed in units of memory block. The erase sequence may indicate a series of operations which are performed to set cell states of all memory cells in a memory block to the erase state. The erase sequence may include the pre-program operation, the erase operation, and the erase verify operation

Assuming that the pre-program operation is not performed, when the erase operation is performed, some of memory cells may be in the program state, but the others thereof may be in the erase state. When the erase state is performed under the above state, because not only threshold voltages of memory cells being in the program state but also threshold voltages of memory cells being in the erase state further decrease, the breadth width of the threshold voltage distribution corresponding to the erase state may become wider. To prevent the above issue, the program operation on all the memory cells may be performed before the erase operation. This operation may be referred to as a “pre-program operation”.

As described above, because the pre-program operation is performed in units of memory block, the pre-program operation on the first sub-memory block and the pre-program operation on the second sub-memory block may be simultaneously performed. In this case, the first common source line CSL1 and the second common source line CSL2 may share the first common source driver.

For example, referring to FIG. 13, the timing diagram from a first time point t1 to a sixth time point t6 is illustrated. The chronological order of the first to sixth time points t1 to t6 is as follows: the first time point t1, the second time point t2, the third time point t3, the fourth time point t4, the fifth time point t5, and the sixth time point t6.

The memory device may apply the program voltage to the selected word line WL_sel. For example, from the first time point t1 to the second time point t2, the pass voltage Vpass may be applied to the selected word line WL_sel. From the second time point t2 to the fourth time point t4, the first program voltage Vpgm1 greater than the pass voltage Vpass may be applied to the selected word line WL_sel. From the fourth time point t4 to the sixth time point t6, the second program voltage Vpgm2 greater than the first program voltage Vpgm1 may be applied to the selected word line WL_sel.

The pre-program operation may include shutting off the first string selection line SSL1. For example, the first string selection voltage VS1 may be applied to the first string selection line SSL1 from the first time point t1 to the third time point t3, and a turn-off voltage (e.g., the ground voltage GND) may be applied to the first string selection line SSL1 from the third time point t3.

The pre-program operation may include shutting off the first ground selection line GSL1. For example, the first ground selection voltage VG1 may be applied to the first ground selection line GSL1 from the first time point t1 to the third time point t3, and the turn-off voltage (e.g., the ground voltage GND) may be applied to the first ground selection line GSL1 from the third time point t3.

Afterwards, at the fourth time point t4, as the voltage applied to the selected word line WL_sel increases to the second program voltage Vpgm2, a voltage of a first channel CH1 of the first sub-memory block may increase to a first channel voltage Vch1.

Unlike the above description, from the first time point t1 to the sixth time point t6, the second string selection voltage VS2 and the second ground selection voltage VG2 may be respectively applied to the second string selection line SSL2 and the second ground selection line GSL2.

In this case, a voltage of a second channel CH2 may be maintained at the ground voltage GND.

That is, the memory device according to the present disclosure may decrease the speed of the pre-program operation on the first sub-memory block. Accordingly, a difference between the speed of the pre-program operation on the first sub-memory block and the speed of the pre-program operation on the second sub-memory block may be compensated for.

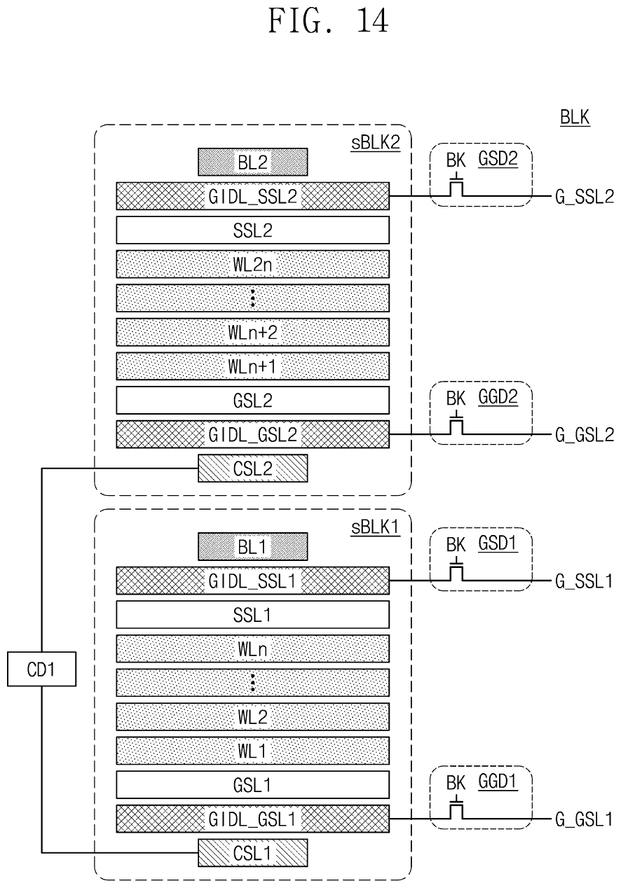

FIG. 14 is a diagram schematically illustrating an example of a cross section of a memory block further including selection lines. Referring to FIG. 14, the first sub-memory block sBLK1 may further include a first GIDL ground selection line GIDL_GSL1 and a first GIDL string selection line GIDL_SSL1, and the second sub-memory block sBLK2 may further include a second GIDL ground selection line GIDL_GSL2 and a second GIDL string selection line GIDL_SSL2.

The first GIDL string selection line GIDL_SSL1 is stacked between the first bit line BL1 and the first string selection line SSL1. The first GIDL string selection line GIDL_SSL1 may be connected to a first GIDL string selection driver GSD1.

The first GIDL ground selection line GIDL_GSL1 is stacked between the first common source line CSL1 and the first ground selection line GSL1. The first GIDL ground selection line GIDL_GSL1 may be connected to a first GIDL ground selection driver GGD1.

The second GIDL string selection line GIDL_SSL2 is stacked between the second bit line BL2 and the second string selection line SSL2. The second GIDL string selection line GIDL_SSL2 may be connected to a second GIDL string selection driver GSD2.

The second GIDL ground selection line GIDL_GSL2 is stacked between the second common source line CSL2 and the second ground selection line GSL2. The second GIDL ground selection line GIDL_GSL2 may be connected to a second GIDL ground selection driver GGD2.

The first GIDL string selection driver GSD1, the first GIDL ground selection driver GGD1, the second GIDL string selection driver GSD2, and the second GIDL ground selection driver GGD2 may be included in the first wafer or the second wafer.

Each of the first GIDL string selection driver GSD1, the first GIDL ground selection driver GGD1, the second GIDL string selection driver GSD2, and the second GIDL ground selection driver GGD2 may include a drive transistor. Each drive transistor may be turned on or turned off by a blocking voltage BK input to a gate thereof.

In this case, the first common source line CSL1 and the second common source line CSL2 may share the first common source driver CD1.

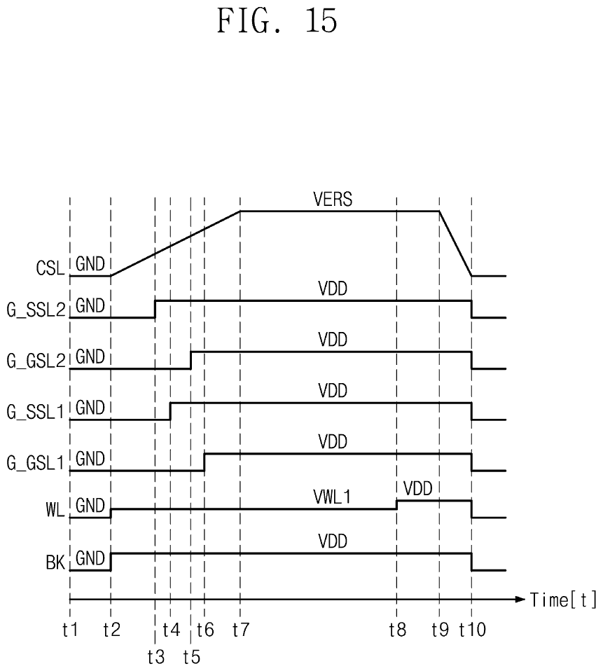

FIG. 15 is a timing diagram describing an example of an erase operation in an erase sequence of a memory block. Referring to FIG. 15, there are illustrated changes in voltages associated with the erase operation over time when the first common source line CSL1 and the second common source line CSL2 share the first common source driver CD1. In FIG. 15, the horizontal axis represents a time, and the vertical axis represents a magnitude of a voltage. Components illustrated in FIG. 15 respectively correspond to components having the same reference signs in the above drawings.

The erase operation may be performed in units of memory block. Accordingly, the erase operation on the first sub-memory block and the erase operation on the second sub-memory block may be simultaneously performed.

The common source line CSL may correspond to the first common source line CSL1 (or the second common source line CSL2). The word line WL may correspond to the first to n-th word lines (or the (n+1)-th to 2n-th word lines).

For example, referring to FIG. 15, the timing diagram from a first time point t1 to a tenth time point t10 is illustrated. The chronological order of the first to tenth time points t1 to t10 is as follows: the first time point t1, the second time point t2, the third time point t3, the fourth time point t4, the fifth time point t5, the sixth time point t6, the seventh time point t7, the eighth time point t8, the ninth time point t9, and the tenth time point t10.

From the first time point t1 to the second time point t2, voltages applied to the common source line CSL, the first GIDL string selection line GIDL_SSL1, the first GIDL ground selection line GIDL_GSL1, the second GIDL string selection line GIDL_SSL2, and the second GIDL ground selection line GIDL_GSL2 and the blocking voltage BK may be the ground voltage GND.

From the second time point t2 to the tenth time point t10, the blocking voltage BK may be the power supply voltage VDD.

The erase operation may include applying a common source voltage increasing with a first slope to the common source line CSL from the second time point t2 to the seventh time point t7. The first slope may correspond to a voltage increase from the ground voltage GND to an erase voltage VERS during a time period from t2 to t7.

Before the magnitude of the voltage applied to the common source line CSL reaches the erase voltage VERS, the common source line CSL, the first GIDL string selection line GIDL_SSL1, the first GIDL ground selection line GIDL_GSL1, the second GIDL string selection line GIDL_SSL2, and the second GIDL ground selection line GIDL_GSL2 may be floated.

At the third time point t3, the erase operation may include floating the second GIDL string selection line GIDL_SSL2. For example, at the third time point t3, when a second GIDL string selection voltage G_SSL2 applied to the second GIDL string selection line GIDL_SSL2 is the power supply voltage VDD, the drive transistor of the second GIDL string selection driver is incapable of being turned off. Accordingly, the second GIDL string selection line GIDL_SSL2 is floated.

At the fourth time point t4, the erase operation may include floating the first GIDL string selection line GIDL_SSL1. For example, at the fourth time point t4, when a first GIDL string selection voltage G_SSL1 applied to the first GIDL string selection line GIDL_SSL1 is the power supply voltage VDD, the drive transistor of the first GIDL string selection driver is incapable of being turned off. Accordingly, the first GIDL string selection line GIDL_SSL1 is floated.

At the fifth time point t5, the erase operation may include floating the second GIDL ground selection line GIDL_GSL2. For example, at the fifth time point t5, when a second GIDL ground selection voltage G_GSL2 applied to the second GIDL ground selection line GIDL_GSL2 is the power supply voltage VDD, the drive transistor of the second GIDL ground selection driver is incapable of being turned off. Accordingly, the second GIDL ground selection line GIDL_GSL2 is floated.

At the sixth time point t6, the erase operation may include floating the first GIDL ground selection line GIDL_GSL1. For example, at the sixth time point t6, when a first GIDL ground selection voltage G_GSL1 applied to the first GIDL ground selection line GIDL_GSL1 is the power supply voltage VDD, the drive transistor of the first GIDL ground selection driver is incapable of being turned off. Accordingly, the first GIDL ground selection line GIDL_GSL1 is floated.

As the memory device differently sets the floating time points of the first GIDL string selection line GIDL_SSL1 and the second string selection line SSL2 and differently sets the first GIDL ground selection line GIDL_GSL1 and the second ground selection line GSL2, the memory device may compensate for a difference between the speed of the erase operation on the first sub-memory block and the speed of the erase operation on the second sub-memory block.

For example, to decrease the speed of the erase operation on the first sub-memory block, the memory device may float the first GIDL string selection line GIDL_SSL1 at a time point (i.e., the third time point t3) later than a time point (i.e., the second time point t2) at which the second GIDL string selection line GIDL_SSL2 is floated. Also, the memory device may float the first GIDL ground selection line GIDL_GSL1 at a time point (i.e., the fifth time point t5) later than a time point (i.e., the fourth time point t4) at which the second GIDL ground selection line GIDL_GSL2 is floated.

A first word line voltage VWL1 may be applied to the word line WL from the second time point t2 to the eighth time point t8, the power supply voltage VDD may be applied to the word line WL from the eighth time point t8 to the ninth time point t9, and the ground voltage GND may be applied to the word line WL after the ninth time point t9.

According to the above description, the erase operation on memory cells connected to the word lines WL are performed before the eighth time point t8, and the drive transistor of the word line driver connected to the word line WL8 is then turned off at the eighth time point t8. Accordingly, the erase operation stops.

From the ninth time point t9 to the tenth time point t10, the magnitude of the voltage of the common source line CSL gradually decreases from the erase voltage VERS to the ground voltage GND.

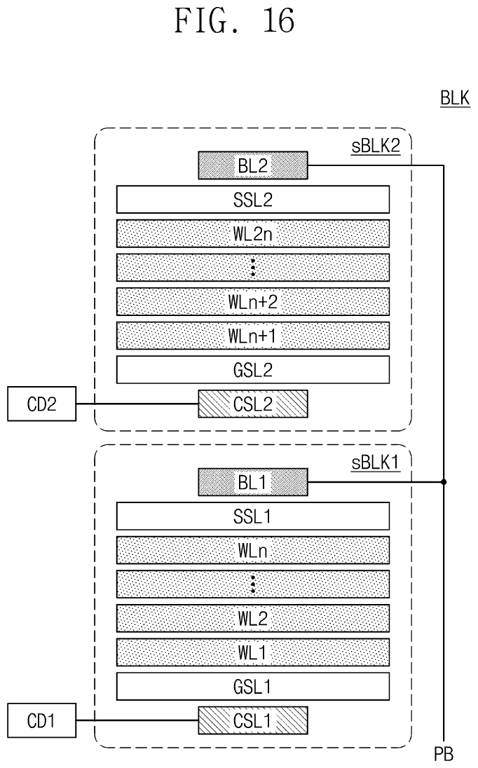

FIG. 16 is a diagram schematically illustrating an example of a cross section of the memory block BLK connected to two common source drivers.

The first common source driver CD1 may be connected to the first sub-memory block sBLK1. The second common source driver CD2 may be connected to the second sub-memory block sBLK2.

In other words, the first common source line CSL1 and the second common source line CSL2 may be independently controlled.

For convenience, the description which is given with reference to FIG. 5 will be omitted to avoid redundancy.

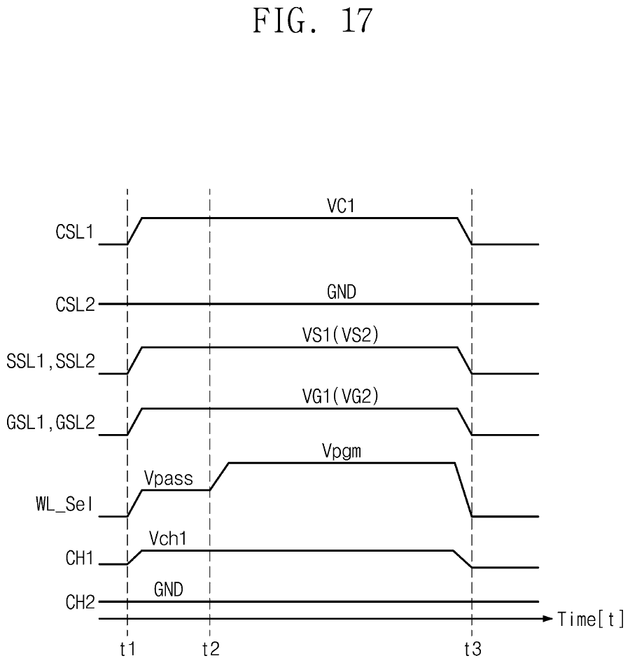

FIG. 17 is a timing diagram describing an example of a pre-program operation in an erase sequence of a memory block of FIG. 16. Referring to FIG. 17, there are illustrated changes in voltages associated with the pre-program operation over time when the first common source line CSL1 is connected to a first common source driver and the second common source line CSL2 is connected to a second common source driver.

For convenience, the description which is given with reference to FIG. 13 will be omitted to avoid redundancy.

For example, referring to FIG. 17, the timing diagram from a first time point t1 to a third time point t3 is illustrated. The chronological order of the first to third time points t1 to t3 is as follows: the first time point t1, the second time point t2, and the third time point t3.

The memory device may apply the program voltage Vpgm to the selected word line WL_sel. For example, from the first time point t1 to the second time point t2, the pass voltage Vpass may be applied to the selected word line WL_sel. From the second time point t2 to the third time point t3, the program voltage Vpgm greater than the pass voltage Vpass may be applied to the selected word line WL_sel.

From the first time point t1 to the third time point t3, the first string selection voltage VS1 (or the second string selection voltage VS2) may be applied to the first string selection line SSL1 and the second string selection line SSL2.

From the first time point t1 to the third time point t3, the first ground selection voltage VG1 (or the second ground selection voltage VG2) may be applied to the first ground selection line GSL1 and the second ground selection line GSL2.

The pre-program operation may include applying the first common source voltage VC1 to the first common source line CSL1 from the first time point t1 to the third time point t3. According to the above description, a voltage of the first channel CH1 may gradually increase from the first time point t1 and may then reach the first channel voltage Vch1.

Accordingly, the memory device may decrease the speed of the pre-program operation on the first sub-memory block.

The pre-program operation may include applying the ground voltage GND to the second common source line CSL2 from the first time point t1 to the third time point t3. In this case, a voltage of the second channel CH2 may be maintained at the ground voltage GND.

In other words, the memory device may decrease a difference between the speed of the pre-program operation on the first sub-memory block and the speed of the pre-program operation on the second sub-memory block.

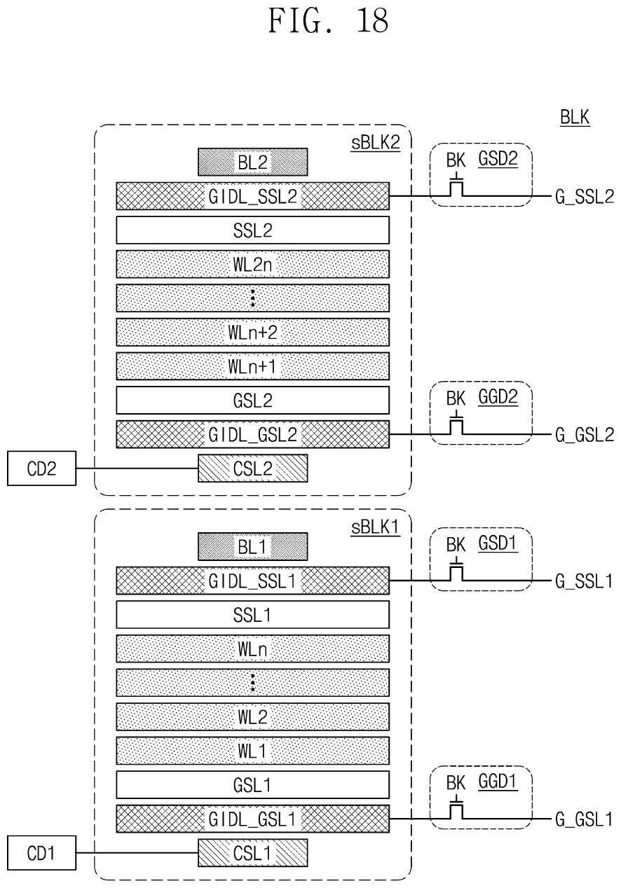

FIG. 18 is a diagram schematically illustrating an example of a cross section of the memory block BLK of FIG. 16, which further includes GIDL lines.

For convenience, the description which is given with reference to FIG. 14 will be omitted to avoid redundancy.

The first sub-memory block sBLK1 may be further include the first GIDL string selection line GIDL_SSL1 and the first GIDL ground selection line GIDL_GSL1. The second sub-memory block sBLK2 may be further include the second GIDL string selection line GIDL_SSL2 and the second GIDL ground selection line GIDL_GSL2.

The first sub-memory block sBLK1 may be connected to the first common source driver CD1. The second sub-memory block sBLK2 may be connected to the second common source driver CD2.

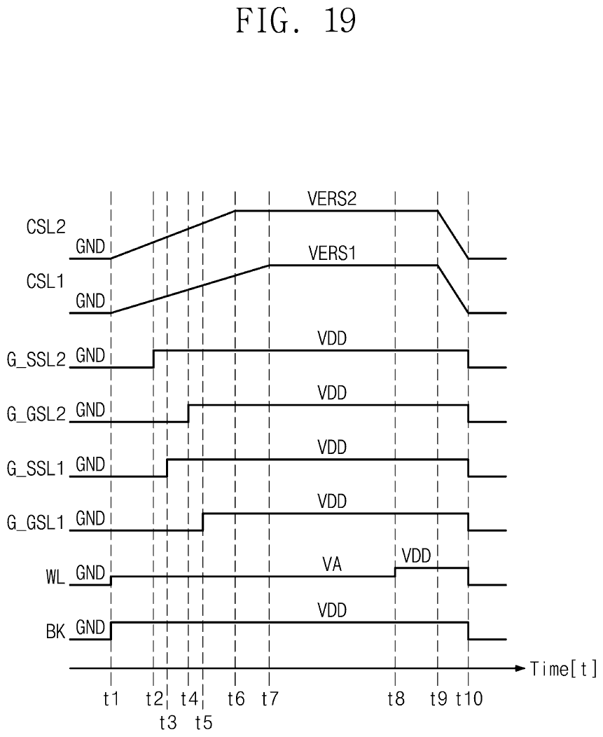

FIG. 19 is a timing diagram describing an example of an erase operation in an erase sequence of a memory block of FIG. 18. Referring to FIG. 19, there are illustrated changes in voltages associated with the erase operation over time when the first common source line CSL1 is connected to the first common source driver and the second common source line CSL2 is connected to the second common source driver. In FIG. 19, the horizontal axis represents a time, and the vertical axis represents a magnitude of a voltage. Components illustrated in FIG. 19 respectively correspond to components having the same reference signs in the above drawings.

The erase operation may be performed in units of memory block. Accordingly, the erase operation on the first sub-memory block and the erase operation on the second sub-memory block may be simultaneously performed.

The word line WL may correspond to the first to n-th word lines (or the (n+1)-th to 2n-th word lines). The blocking voltage BK may correspond to a voltage which is applied to the gate of the drive transistor of each of a first GIDL string selection driver, a first GIDL ground selection driver, a second GIDL string selection driver, and a second GIDL ground selection driver.

For example, referring to FIG. 19, the timing diagram from a first time point t1 to a tenth time point t10 is illustrated. The chronological order of the first to tenth time points t1 to t10 is as follows: the first time point t1, the second time point t2, the third time point t3, the fourth time point t4, the fifth time point t5, the sixth time point t6, the seventh time point t7, the eighth time point t8, the ninth time point t9, and the tenth time point t10.

From the second time point t2 to the tenth time point t10, the blocking voltage BK may be the power supply voltage VDD.

The erase operation may include applying a common source voltage increasing with a first slope to the first common source line CSL1 from the second time point t1 to the seventh time point t7. The first slope may correspond to a voltage increase from the ground voltage GND to a first erase voltage VERS1 during a time period from t1 to t7.

The erase operation may include applying a common source voltage increasing with a second slope to the second common source line CSL2 from the second time point t1 to the sixth time point t6. The second slope may correspond to a voltage increase from the ground voltage GND to a second erase voltage VERS2 during the time period from t1 to t6.

In some implementations, the second slope may be greater than the first slope.

In some implementations, the second erase voltage VERS2 may be greater than the first erase voltage VERS1.

Accordingly, the memory device may increase the speed of the erase operation on the second sub-memory block. That is, a difference between the speed of the erase operation on the first sub-memory block and the speed of the erase operation on the second sub-memory block may decrease.

Before the seventh time point t7 at which the magnitude of the voltage applied to the first common source line CSL1 reaches the first erase voltage VERS1, the first GIDL string selection line GIDL_SSL1, the first GIDL ground selection line GIDL_GSL1, the second GIDL string selection line GIDL_SSL2, and the second GIDL ground selection line GIDL_GSL2 may be floated.

Although not illustrated, the erase operation may include applying the power supply voltage VDD to the first GIDL string selection line GIDL_SSL1 at the third time point t3 and the second GIDL string selection line GIDL_SSL2 at the second time point t2. Also, the erase operation may include applying the power supply voltage VDD to the first GIDL ground selection line GIDL_GSL1 at the fifth time point t5 and the second GIDL ground selection line GIDL_GSL2 at the fourth time point t4.

An erase operation speed difference may decrease by differently setting floating time points of GIDL lines of respective sub-memory blocks in addition to adjusting the rising slopes of the first common source line CSL1 and the second common source line CSL2 and magnitudes of erase voltages of the first common source line CSL1 and the second common source line CSL2.

For example, as illustrated, the erase operation may include floating the second GIDL string selection line GIDL_SSL2 at the second time point t2. The erase operation may include floating the first GIDL string selection line GIDL_SSL1 at the third time point t3. The erase operation may include floating the second GIDL ground selection line GIDL_GSL2 at the fourth time point t4. The erase operation may include floating the first GIDL ground selection line GIDL_GSL1 at the fifth time point t5.

FIG. 20 is a block diagram of an example of a memory system 1000. Referring to FIG. 20, the memory system 1000 may include the memory controller 1100 and a non-volatile memory device 1200. The memory device 1200 correspond to the memory device 100 of FIG. 1.

The memory system 1000 may store data which are accessed by a host such as a mobile phone, an MP3 player, a laptop computer, a desktop computer, a game console, a television (TV), or an in-vehicle infotainment system.

The memory system 1000 may be manufactured with any one of various kinds of storage devices which are connected to the host in compliance with an interface protocol. For example, the memory system 1000 may be implemented with any one of various kinds of storage devices such as a solid state drive (SSD), a multimedia card such as MMC, eMMC, RS-MMC, or a micro-MMC, a secure digital cards such as an SD, a mini-SD, or a micro-SD, a universal storage bus (USB) storage device, a universal flash storage (UFS) device, a personal computer memory card international association (PCMCIA) card type of storage device, a PCI-express (PCI-E) card type of storage device, a compact flash (CF) card, a smart media card, and a memory stick.

The memory system 1000 may be manufactured with any one of various kinds of package forms. For example, the memory system 1000 may be manufactured with any one of various kinds of package forms such as a package on package (POP), a system in package (SIP), a system on chip (SOC), a multi-chip package (MCP), a chip on board (COB), a wafer-level fabricated package (WFP), and wafer-level stack package (WSP).

The memory controller 1100 may include a host interface 1110, a processor 1120, a memory 1130, and a memory interface 1140. The processor 1120 may process a request transmitted from the host. To process the request transmitted from the host, the processor 1120 may drive firmware to control internal function blocks of the memory controller 1100 and the memory device 1200. The memory 1130 may store the firmware which is driven by the processor 1120. Also, the memory 1130 may store data necessary to drive the firmware, for example, meta data. The memory 1130 may include a data buffer for temporarily storing write data to be transmitted from the host to the memory device 1200 or read data to be transmitted from the memory device 1200 to the host. The memory 1130 may receive and store map data from the memory device 1200 when the memory system 1000 is booted up. The map data may include first map data including logical to physical (L2P) information about a memory block where data are stored and second map data including physical to logical (P2L) information.

The memory controller 1100 may determine whether the data received from the host are hot data or cold data. The hot data may mean data with a high read frequency, and the cold data may mean data with a relatively low read frequency.

The memory device 1200 may include a first wafer and a second wafer. The first wafer includes a first sub-memory block. The first sub-memory block may include first to n-th word lines, a first bit line, a first string selection line, and a first ground selection line. The second wafer includes a second sub-memory block. The second sub-memory block may include (n+1)-th to 2n-th word lines, a second bit line, a second string selection line, and a second ground selection line.

In this case, the first to n-th word lines may be respectively connected to the (n+1)-th to 2n-th word lines. The first to n-th word lines may share first to n-th word line drivers with the (n+1)-th to 2n-th word lines.

Also, the first bit line may be connected to the second bit line. The first bit line and the second bit line may share a page buffer.

For convenience, the description which is given with reference to FIGS. 1 to 19 will be omitted to avoid redundancy.

According to some implementations of the present disclosure, a memory device in which a plurality of wafers are stacked and a memory system including the same are provided.

Also, according to implementations of the present disclosure, a memory device which operates while compensating for an electrical characteristic difference of the plurality of wafers and a memory system including the same are provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A memory device comprising:
a first wafer including a first sub-memory block, a first bit line, a first string selection line, and a first ground selection line, the first sub-memory block being connected to a 1^{st} word line through an n^{th} word line, wherein n is a natural number greater than 1; and
a second wafer on the first wafer in a vertical direction and including a second sub-memory block, a second bit line, a second string selection line, and a second ground selection line, the second sub-memory block being connected to an (n+1)^{th} word line through a (2n)^{th} word line,
wherein the 1^{st} word line through the n^{th} word line are respectively connected to the (n+1)^{th} word line through the (2n)^{th} word line and share a 1^{st} word line driver through an n^{th} word line driver with the (n+1)^{th} word line through the (2n)^{th} word line,
wherein the first bit line is connected to the second bit line and shares a first page buffer with the second bit line,
wherein the first string selection line is connected to a first string selection driver, and the second string selection line is connected to a second string selection driver, and
wherein the first ground selection line is connected to a first ground selection driver, and the second ground selection line is connected to a second ground selection driver.

2. The memory device of claim 1, wherein the first wafer includes the 1^{st} word line driver through the n^{th} word line driver, the first page buffer, the first string selection driver, the second string selection driver, the first ground selection driver, and the second ground selection driver.

3. The memory device of claim 1, wherein the first wafer includes:
a control circuit configured to control the first page buffer and a plurality of drivers to compensate for at least one of a first difference between a first speed of a first memory operation on the first sub-memory block and a second speed of a second memory operation on the second sub-memory block and a second difference between a first plurality of loads of a first plurality of lines connected to the first sub-memory block and a second plurality of loads of a second plurality of lines connected to the second sub-memory block, the plurality of drivers being connected to the first sub-memory block and the second sub-memory block.

4. The memory device of claim 1, wherein the first page buffer includes a sensing transistor,
wherein, in each of a first read operation on the first sub-memory block and a second read operation on the second sub-memory block, the first bit line and the second bit line are configured to connect to the first page buffer based on the sensing transistor being turned on, and are configured to float so as to disconnect from the first page buffer based on the sensing transistor being turned off, and
wherein the memory device is configured to set, in each of the first read operation on the first sub-memory block and the second read operation on the second sub-memory block, a different voltage magnitude or a different application time of at least one voltage applied to a respective word line and a respective bit line.

5. The memory device of claim 1, wherein the memory device is configured to:
during a first read operation on the first sub-memory block, apply a first read voltage to a first word line among the 1^{st} word line through the n^{th} word line during a first time period, and
during a second read operation on the second sub-memory block, apply a second read voltage greater than the first read voltage to a second word line among the (n+1)^{th} word line through the (2n)^{th} word line during the first time period.

6. The memory device of claim 1, wherein the memory device is configured to:
during a first read operation on the first sub-memory block, apply a first bit line voltage to the first bit line during a second time period, and
during a second read operation on the second sub-memory block,
apply the first bit line voltage to the second bit line during a third time period that is longer than the second time period;
apply a second bit line voltage greater than the first bit line voltage to the second bit line during the second time period; or
apply the second bit line voltage to the second bit line during the third time period.

7. The memory device of claim 1, wherein the first page buffer includes a sensing transistor,
wherein, based on the sensing transistor being turned on, the first bit line and the second bit line are configured to electrically connect to the first page buffer,
wherein, based on the sensing transistor being turned off, the first bit line and the second bit line are configured to float so as to disconnect from the first page buffer,
wherein the memory device is configured to:
during a first read operation on the first sub-memory block, apply a first sensing gate voltage to the sensing transistor during a fourth time period, and
during a second read operation on the second sub-memory block,
apply the first sensing gate voltage to the sensing transistor during a fifth time period that is longer than the fourth time period;
apply a second sensing gate voltage greater than the first sensing gate voltage to the sensing transistor during the fourth time period; or
apply the second sensing gate voltage to the sensing transistor during the fifth time period.

8. The memory device of claim 1, wherein the first sub-memory block is connected to a first source line driver through a first common source line, and
wherein the second sub-memory block is connected to the first source line driver through a second common source line.

9. The memory device of claim 8, wherein, in a first pre-program operation in an erase sequence associated with the first sub-memory block and during a sixth time period, the first string selection line and the first ground selection line are shut off.

10. The memory device of claim 9, wherein during the first pre-program operation, the memory device is configured to:
apply, to the first string selection line, a first string selection voltage so as to turn off a first string selection transistor connected to the first string selection line during the sixth time period;
and apply, to the first ground selection line, a first ground selection voltage so as to turn off a first ground selection transistor connected to the first ground selection line during the sixth time period.

11. The memory device of claim 8, wherein the first wafer includes:
a first GIDL string selection line between the first bit line and the first string selection line; and
a first GIDL ground selection line between the first common source line and the first ground selection line,
wherein the second wafer includes:
a second GIDL string selection line between the second bit line and the second string selection line; and
a second GIDL ground selection line between the second common source line and the second ground selection line,
wherein during an erase operation in an erase sequence associated with the first sub-memory block and the second sub-memory block, the memory device is configured to:
during a first time period, apply a first common source voltage to the first common source line, wherein the first common source voltage has a first increasing slope;
at a first time point in the first time period, float the second GIDL string selection line;
at a second time point following the first time point in the first time period, float the first GIDL string selection line;
at a third time point following the second time point in the first time period, float the second GIDL ground selection line; and
at a fourth time point following the third time point in the first time period, float the first GIDL ground selection line.

12. The memory device of claim 8, wherein the memory device is configured to:
set, in each of a first program operation on the first sub-memory block and a second program operation on the second sub-memory block, a different voltage magnitude or a different application time of at least one voltage, applied to a respective unselected word line, a respective selected word line, a respective string selection line, a respective ground selection line, a respective inhibit bit line, and a force voltage.

13. The memory device of claim 1, wherein the first sub-memory block is connected to a first source line driver through a first common source line, and
wherein the second sub-memory block is connected to a second source line driver through a second common source line.

14. The memory device of claim 13, wherein the memory device is configured to:
set, in each of a first program operation on the first sub-memory block and a second program operation on the second sub-memory block, a different voltage magnitude or a different application time of at least one voltage, applied to a respective unselected word line, a respective selected word line, a respective string selection line, a respective ground selection line, a respective common source line, and a respective inhibit bit line, and a force voltage.

15. The memory device of claim 13, wherein the memory device is configured to:
during a first program operation on the first sub-memory block and during a first target time period, apply a first voltage to a first target line connected to the first sub-memory block,
during a second program operation on the second sub-memory block and during a second target time period longer than the first target time period, apply the first voltage to a second target line connected to the second sub-memory block and corresponding to the first target line;
during the first target time period, apply a second voltage greater than the first voltage to the second target line; and
during the second target time period, apply the second voltage to the second target line, and
wherein the first target line is one of the first string selection line, the first ground selection line, a selected word line among the 1^{st} word line through the n^{th} word line, an unselected word line of the 1^{st} word line through the n^{th} word line, and an inhibit bit line.

16. The memory device of claim 13, wherein during a pre-program operation in an erase sequence associated with the first sub-memory block and the second sub-memory block, the memory device is configured to:
during a first time period, apply a first common source voltage to the first common source line; and
during the first time period, apply, to the second common source line, a second common source line voltage so as to turn off a second common source line transistor connected to the second common source line.

17. The memory device of claim 13, wherein the first wafer includes:
a first GIDL string selection line between the first bit line and the first string selection line; and
a first GIDL ground selection line between the first common source line and the first ground selection line,
wherein the second wafer includes:
a second GIDL string selection line between the second bit line and the second string selection line; and
a second GIDL ground selection line between the second common source line and the second ground selection line,
wherein during an erase operation in an erase sequence associated with the first sub-memory block and the second sub-memory block, the memory device is configured to:
during a first time period, apply a first common source voltage to the first common source line, the first common source voltage comprising an increasing first slope; and
during a second time period in the first time period, apply a second common source voltage to the second common source line, the second common source voltage comprising an increasing second slope that is greater than the first slope.

18. The memory device of claim 17, wherein during the erase operation, the memory device is configured to:
at a fifth time point in the second time period, float the second GIDL string selection line;
at a sixth time point following the fifth time point in the second time period, float the first GIDL string selection line;
at a seventh time point following the sixth time point in the second time period, float the second GIDL ground selection line; and
at an eighth time point following the seventh time point in the second time period, float the first GIDL ground selection line.

19. A memory system comprising:
a memory controller configured to generate a command indicating a memory operation; and
a memory device configured to perform the memory operation based on the command,
wherein the memory device includes:
a first wafer including a first sub-memory block, a first bit line, a first string selection line, and a first ground selection line, the first sub-memory block being connected to a 1 word line through an n^{th} word line, wherein n is a natural number greater than 1; and
a second wafer on the first wafer in a vertical direction and including a second sub-memory block, a second bit line, a second string selection line, and a second ground selection line, the second sub-memory block being connected to a (n+1)^{th} word line through (2n)^{th} word line,
wherein the 1^{st} word line through the n^{th} word line are respectively connected to the (n+1)^{th} word line through the (2n)^{th} word line and share 1^{st} word line drive to n^{th} word line driver with the (n+1)^{th} word line through the (2n)^{th} word line,
wherein the first bit line is connected to the second bit line and shares a first page buffer with the second bit line,
wherein the first string selection line is connected to a first string selection driver, and the second string selection line is connected to a second string selection driver, and
wherein the first ground selection line is connected to a first ground selection driver, and the second ground selection line is connected to a second ground selection driver.

20. A memory device comprising:
a first wafer including a first sub-memory block, wherein the first sub-memory block is connected to a first string selection line and a first ground selection line; and
a second wafer on the first wafer in a vertical direction and including a second sub-memory block, wherein the second sub-memory block is connected to a second string selection line and a second ground selection line,
wherein the first sub-memory block and the second sub-memory block share a 1^{st} word line through an n^{th} word line and a first bit line,
wherein, during a plurality of memory operations associated with the first sub-memory block and the second sub-memory block, the memory device is configured to set, in each of the first sub-memory block and the second sub-memory block, a different voltage magnitude or a different application time of a voltage applied to at least one line connected to each of the first sub-memory block and the second sub-memory block.
